(19) United States
(12) Patent Application Publication
(10) Pub. No.: US 2026/0324332 A1
(43) Pub. Date: Oct. 15, 2026

(54) MANUFACTURING SEMICONDUCTOR DEVICES USING A LASER

(71) Applicant: Samsung Electronics Co., Ltd., Suwon-si (KR)

(72) Inventor: Junghyun Roh, Suwon-si (KR)

(21) Appl. No.: 19/563,799

(22) Filed: Mar. 11, 2026

(30) Foreign Application Priority Data
Apr. 11, 2025 (KR) 10-2025-0047653

(51) Int. Cl. H10P 54/30; B23K 26/064; B23K 26/364; B23K 26/53; B23K 26/60; B23K 101/40; H10P 54/20; H10P 54/92; H10P 58/00

(52) U.S. Cl. CPC H10P 54/30; B23K 26/0648; B23K 26/364; B23K 26/53; B23K 26/60; H10P 54/20; H10P 54/92; H10P 58/20; B23K 2101/40

(57) ABSTRACT

Forming a backside layer on a backside of the wafer, forming a recess in the backside layer by emitting a first laser beam onto the backside layer, forming an inner crack inside the wafer by emitting a second laser beam into the wafer through the backside that overlaps the recess, the second laser beam having a wavelength longer than a wavelength of the first laser beam, and separating the chip regions from each other using the inner crack.

### CROSS-REFERENCE TO RELATED APPLICATION

This application claims priority under 35 U.S.C. § 119 to Korean Patent Application No. 10-2025-0047653, filed on Apr. 11, 2025, in the Korean Intellectual Property Office, the entirety of which is incorporated by reference herein.

### BACKGROUND

A semiconductor device can include an integrated circuit constituted by metal oxide semiconductor field effect transistors (MOSFETs). As the size and design rule of the semiconductor device are gradually reduced, the scale-down of the MOS field-effect transistors is also gradually accelerated. The operating characteristics of the semiconductor device may be deteriorated depending on the scale-down of the MOS field-effect transistors. Accordingly, various methods are being studied to form a semiconductor device having better performance while overcoming limitations due to high-integration of the semiconductor device.

### SUMMARY

Some aspects of the present disclosure provide semiconductor device manufacturing methods for etching at least a portion of a backside layer using a laser beam.

According to some implementations of the present disclosure, a wafer cutting method includes preparing a wafer having chip regions and a scribe lane region that defines the chip regions, forming a backside layer on a backside of the wafer, forming a recess in the backside layer by emitting a first laser beam onto the backside layer, forming an inner crack inside the wafer by emitting a second laser beam into the wafer through the backside that overlaps the recess, the second laser beam having a wavelength longer than a wavelength of the first laser beam, and separating the chip regions from each other using the inner crack.

According to some implementations of the present disclosure, a wafer cutting method includes preparing a wafer having chip regions and a scribe lane region that defines the chip regions, forming a backside layer on a backside of the wafer, forming a recess in the backside layer by emitting a first laser beam onto the backside layer, and forming an inner crack inside the wafer by emitting a second laser beam into the wafer through the backside that overlaps the recess, and the emitting of the first laser beam and the emitting of the second laser beam are performed in the same time period.

According to some implementations of the present disclosure, a wafer cutting method includes preparing a wafer having chip regions and a scribe lane region that defines the chip regions, forming a backside layer on a backside of the wafer, forming a recess in the backside layer by emitting a first laser beam onto the backside layer, forming an inner crack inside the wafer by emitting a second laser beam into the wafer through the backside that overlaps the recess, and forming an additional inner crack inside the wafer by emitting a third laser beam into the wafer through the backside that overlaps the recess, and the emitting of the second laser beam and the emitting of the third laser beam are performed in the same time period.

According to some implementations of the present disclosure, a laser cutting apparatus includes a laser beam source, a first optical module, and a second optical module. The laser beam source generates a laser beam and includes a first laser beam source that generates a short-wavelength laser beam and a second laser beam source that generates a long-wavelength laser beam. The first optical module focuses the short-wavelength laser beam, emits the short-wavelength laser beam onto a wafer, and generates a first laser beam to form a recess. The second optical module focuses the long-wavelength laser beam and emits the long-wavelength laser beam into the recess.

The second optical module may generate a second laser beam to form an inner crack inside the wafer.

The second laser beam may have a wavelength longer than a wavelength of the first laser beam.

The first laser beam and the second laser beam may be emitted onto the wafer in the same time period.

The wafer cutting apparatus may further include a beam splitter that adjusts the transmittance of the laser beam, and the beam splitter may include a first beam splitter that adjusts the transmittance of the short-wavelength laser beam and a second beam splitter than adjusts the transmittance of the long-wavelength laser beam.

The first beam splitter may provide the short-wavelength laser beam to the first optical module and/or the second beam splitter.

The first beam splitter may provide the short-wavelength laser beam to the first optical module when the transmittance of the short-wavelength laser beam is set to 100%, may provide the short-wavelength laser beam to the first optical module and the second beam splitter when the transmittance of the short-wavelength laser beam is set to be greater than 0% and less than 100%, and may provide the short-wavelength laser beam to the second beam splitter when the transmittance of the short-wavelength laser beam is set to 0%.

The second beam splitter may provide the long-wavelength laser beam to the second optical module and/or the first beam splitter.

The second beam splitter may provide the long-wavelength laser beam to the second optical module when the transmittance of the long-wavelength laser beam is set to 100%, may provide the long-wavelength laser beam to the second optical module and the first beam splitter when the transmittance of the long-wavelength laser beam is set to be greater than 0% and less than 100%, and may provide the long-wavelength laser beam to the first beam splitter when the transmittance of the long-wavelength laser beam is set to 0%.

The second optical module may generate a second laser beam to form an inner crack inside the wafer and/or a third laser beam to form an additional inner crack inside the wafer.

### BRIEF DESCRIPTION OF THE FIGURES

The above and other objects and features of the present disclosure will become apparent by describing in detail examples thereof with reference to the accompanying drawings.

FIGS. 1 and 2 are flowcharts illustrating examples of semiconductor device manufacturing methods.

FIGS. 3 to 7 are schematic perspective diagrams sequentially illustrating an example of a semiconductor device manufacturing method.

FIG. 8 is a plan view corresponding to ‘F1’of FIG. 5.

FIGS. 9 to 18 are sectional views taken along line I-I′ of FIG. 8, illustrating an example of a semiconductor device manufacturing method.

FIGS. 19, 21, and 23 are sectional views taken along line I′′-I′′′ of FIG. 8.

FIGS. 20, 22, and 24 are plan views showing an enlarged view of line I′′-I′′′ of FIG. 8.

FIGS. 25, 30, 34, 35, 39, 43, and 46 are flowcharts illustrating examples of semiconductor device manufacturing methods.

FIGS. 26, 31, 36, 40, 44, and 47 are schematic perspective diagrams illustrating examples of semiconductor device manufacturing methods.

FIG. 27 is a plan view corresponding to ‘F2’of FIG. 26.

FIGS. 28 and 29 are sectional views taken along line II-II′ of FIG. 27.

FIG. 32 is a plan view corresponding to ‘F3’of FIG. 31.

FIG. 33 is a sectional view taken along line III-III′ of FIG. 31.

FIG. 37 is a plan view corresponding to ‘F4’of FIG. 36.

FIG. 38 is a sectional view taken along line IV-IV′ of FIG. 37.

FIG. 41 is a plan view corresponding to ‘F5’of FIG. 40.

FIG. 42 is a sectional view taken along line V-V′ of FIG. 41.

FIG. 45 is a sectional view taken along to line V-V′ of FIG. 41.

FIG. 48 is a plan view corresponding to ‘F6’of FIG. 47.

FIG. 49 is a sectional view taken along line VI-VI′ of FIG. 48.

FIGS. 50, 51, 52, 53, 54, 55, 56, 57, 58, and 59 are block diagrams illustrating an example of a laser cutting apparatus.

### DETAILED DESCRIPTION

Aspects of the present disclosure describe semiconductor device manufacturing methods, a semiconductor device manufacturing apparatuses using the semiconductor device manufacturing methods, and semiconductor devices manufactured by the semiconductor device manufacturing methods.

The semiconductor device may be manufactured by forming semiconductor devices, such as integrated circuits, on a surface of a semiconductor substrate (e.g., a silicon wafer) that is roughly disk-shaped, and then cutting the semiconductor substrate along defined regions using a wafer cutting apparatus.

A semiconductor device (or semiconductor chip) manufacturing method, a semiconductor device manufactured using the semiconductor device manufacturing method, and a laser cutting apparatus used in the semiconductor device manufacturing method will be sequentially described. The semiconductor device manufacturing method may be a wafer cutting method.

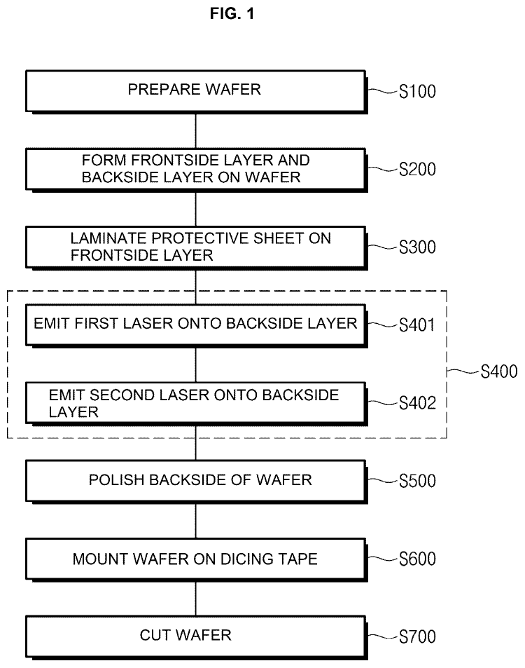

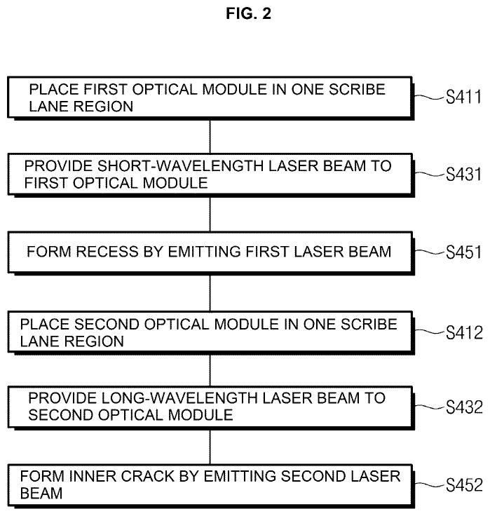

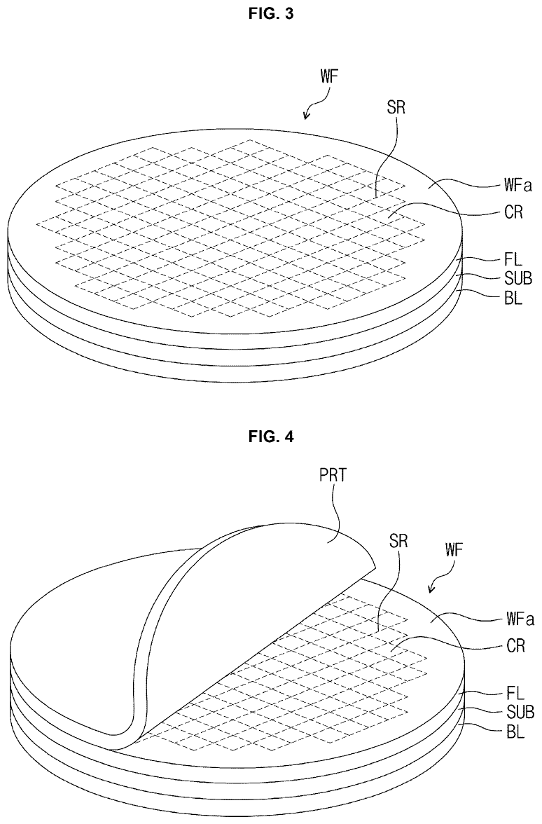

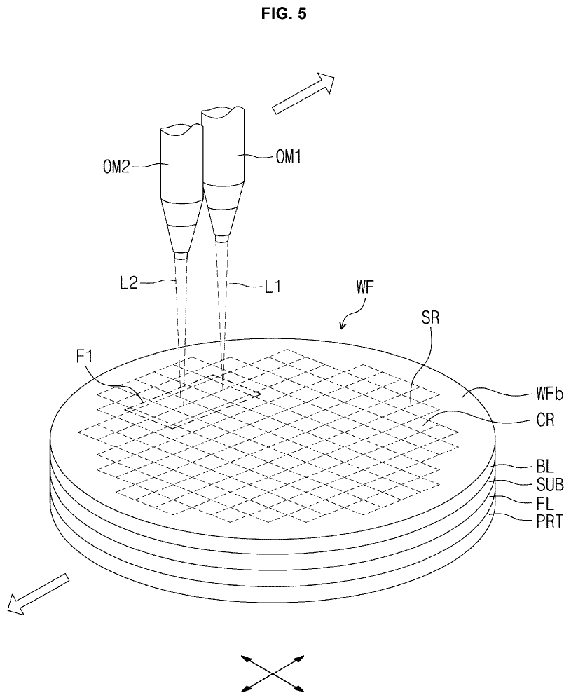

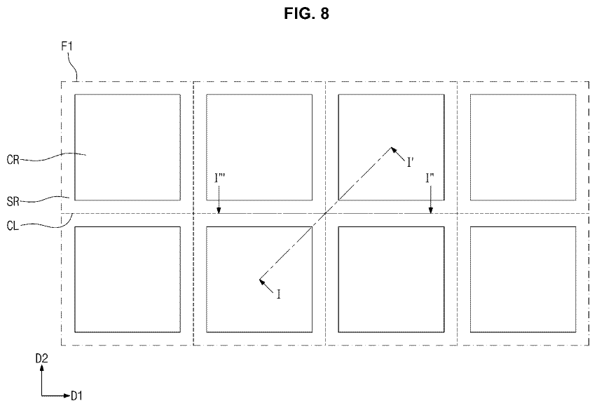

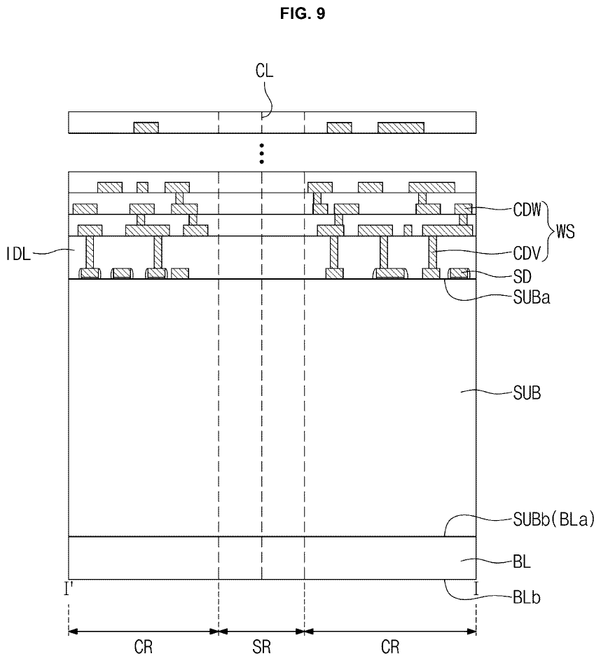

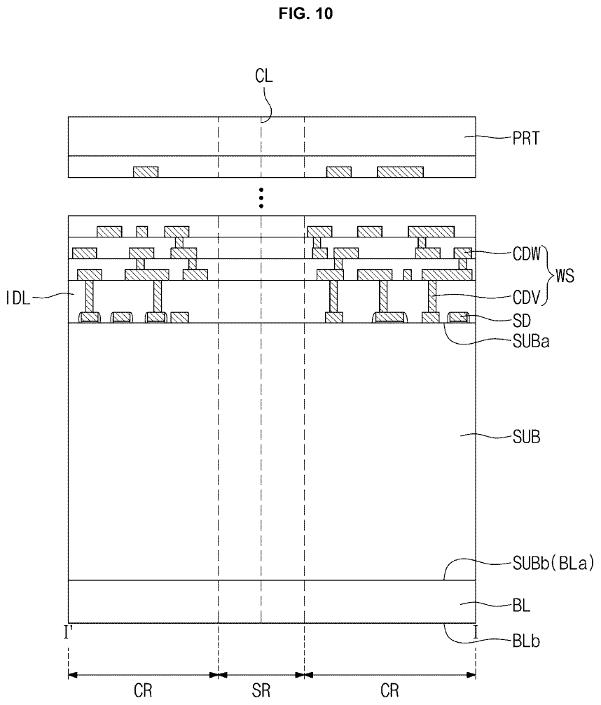

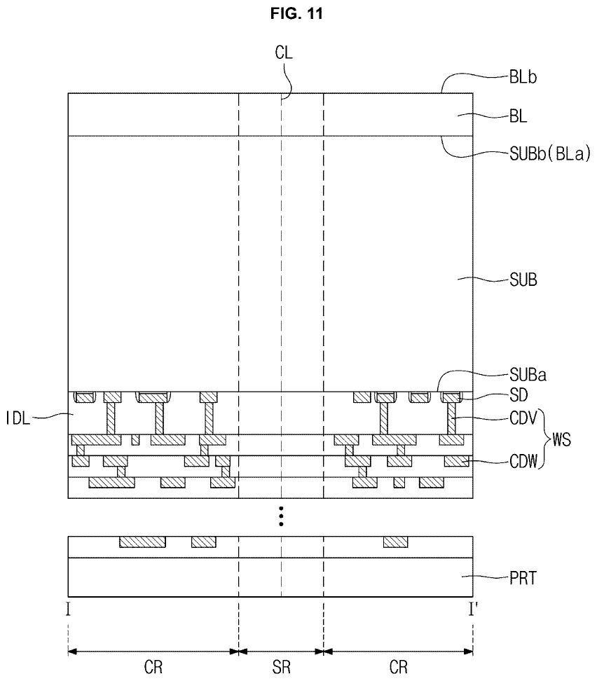

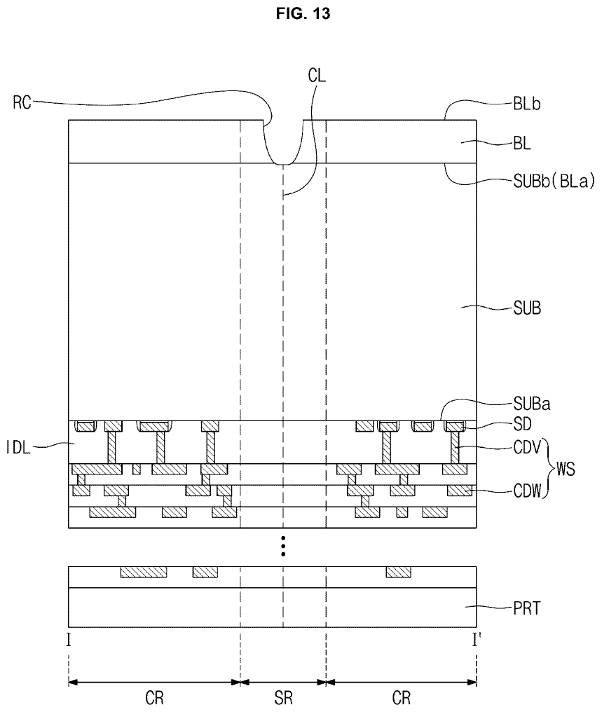

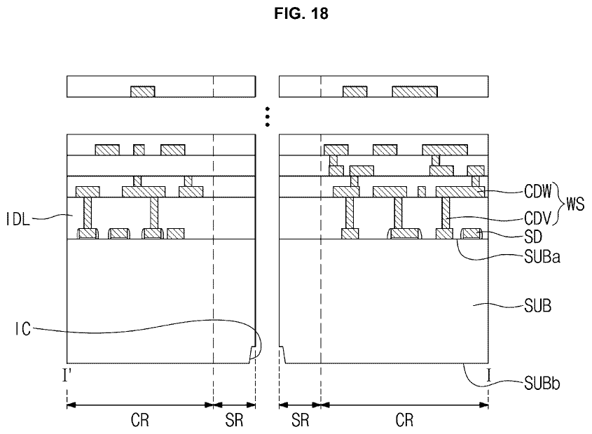

FIGS. 1 and 2 are flowcharts illustrating an example of a semiconductor device manufacturing method. FIGS. 3 to 7 are schematic perspective diagrams sequentially illustrating the semiconductor device manufacturing method. FIG. 8 is a plan view corresponding to ‘F1’ of FIG. 5. FIGS. 9 to 18 are sectional views taken along line I-I′ of FIG. 8.

Referring to FIG. 1, a semiconductor device manufacturing method may include preparing a wafer (S100), forming a frontside layer and a backside layer on the wafer (S200), laminating a protective sheet on the frontside layer (S300), emitting a laser beam onto the backside layer (S400), polishing the backside of the wafer (S500), mounting the wafer on a dicing tape (S600), and cutting the wafer (S700). In this case, the emitting of the laser beam onto the backside layer (S400) may include emitting a first laser beam onto the backside layer (S401) and emitting a second laser beam onto the backside layer (S402). Detailed description thereof will be given below.

Referring to FIGS. 1 and 3, the wafer WF may be formed or provided. The wafer WF may include a substrate, at least one frontside layer FL provided on the frontside of the substrate, and at least one backside layer BL provided on the backside of the substrate. In FIGS. 3 to 8, for convenience of description, each of the frontside layer FL and the backside layer BL is illustrated as a single layer. However, each of the frontside layer FL and the backside layer BL may include multiple layers and/or components.

Referring to FIGS. 1, 3, 8, and 9, the wafer WF may include a base layer SUB having a frontside SUBa and a backside SUBb opposite the frontside SUBa, the frontside layer FL disposed on the frontside SUBa of the base layer SUB, and the backside layer BL disposed on the backside SUBb of the base layer SUB. The wafer WF may include chip regions CR and a scribe lane region SR. The chip regions CR and the scribe lane region SR may include portions of the base layer SUB, the frontside layer FL, and the backside layer BL, and are used as terms for distinguishing the regions of the wafer WF.

The base layer SUB may be a circular (or substantially circular) wafer having a constant thickness. In some implementations, the base layer SUB may mean a substrate that is formed of or includes a semiconductor material and/or a substrate that is used as a base for forming a semiconductor device, even if it does not include a semiconductor material. In some implementations, the base layer SUB may be a silicon wafer. However, without being limited thereto, the base layer SUB may be a wafer including a semiconductor element such as germanium or a compound such as silicon carbide (SiC), gallium arsenide (GaAs), indium arsenide (InAs), or indium phosphide (InP). As another example, the base layer SUB may have a silicon on insulator (SOI) structure. In some implementations, the base layer SUB may include an impurity-doped well or an impurity-doped structure that is a conductive region. The base layer SUB may have various device isolation structures such as a shallow trench isolation (STI) structure.

The frontside layer FL having a plurality of integrated circuit regions may be formed on the frontside SUBa of the base layer SUB. In a subsequent process, the chip regions CR may be separated from one another together with the base layer SUB and may be provided as semiconductor chips.

The chip regions CR may each include one or more semiconductor devices SD. The semiconductor devices SD may be classified as a memory device or a logic device.

The memory device may constitute a volatile memory device or a non-volatile memory device. In some implementations, the volatile memory device may include a memory device such as dynamic random access memory (DRAM), static RAM (SRAM), thyristor RAM (TRAM), zerocapacitor RAM (ZRAM), or twin transistor RAM (TTRAM). In some implementations, the non-volatile memory device may include a memory device such as flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory.

In some implementations, the logic device may be implemented as a microprocessor, a graphics processor, a signal processor, a network processor, an audio codec, a video codec, an application processor, or a system on chip (SOC), but is not limited thereto.

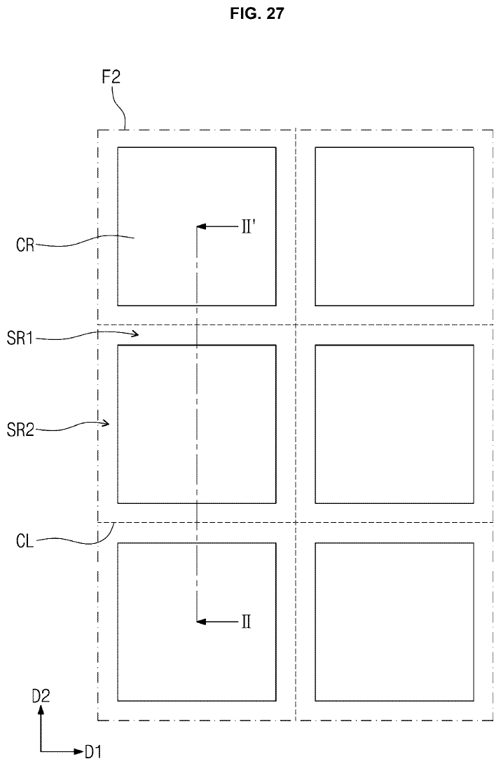

The scribe lane region SR may define the chip regions CR. For example, the chip regions CR may be isolated from one another, or separated from one another, by the scribe lane region SR. The scribe lane region SR may include regions through which cut lines CL pass. In this case, the cut lines CL may be virtual lines. In a cutting process to be described below, the wafer WF may be cut along the cut lines CL. Portion of the scribe lane region SR extending in a row direction and portions extending in a column direction may intersect each other to form the scribe lane region SR. For example, the scribe lane region SR may include first scribe lane regions SR1 extending parallel to each other in a first direction and second scribe lane regions SR2 extending parallel to each other in a second direction crossing the first direction, as shown in FIG. 27. The scribe lane regions SR1, SR2 may be in the form of a straight lane having a constant width. As illustrated in FIG. 3, the chip regions CR may be arranged in rows and columns with the scribe lane region SR therebetween. The chip regions CR may be surrounded by the scribe lane region SR and may be spaced apart from one another.

The chip regions CR may be regions in which the semiconductor devices SD for memory or logic functions are formed. The scribe lane region SR may be a region in which the semiconductor devices are not formed. In some implementations, semiconductor dummy devices may be arranged in the scribe lane region SR.

In some implementations, the frontside layer FL may include an interlayer dielectric layer IDL that is disposed on the frontside SUBa of the base layer SUB and that covers the semiconductor devices SD, and a wiring structure WS disposed on the interlayer dielectric layer IDL and connected to the semiconductor devices SD. The wiring structure WS may have a multilayer wiring structure WS in which insulating layers and conductive wirings CDW are alternately arranged. The conductive wirings CDW of each layer may include conductive vias CDV disposed in a direction perpendicular to the frontside SUBa of the base layer SUB. The conductive wirings CDW and the conductive vias CDV may be formed of a conductive material including at least one of aluminum (Al), copper (Cu), nickel (Ni), tungsten(W), platinum (Pt), or gold (Au). The conductive wirings CDW are illustrated as four or more layers, but their number is not limited thereto. The conductive wirings CDW may be formed in one to three layers or more than four layers.

The interlayer dielectric layer IDL may be formed of a low-k material. The low-k material may be a material having a lower dielectric constant than silicon oxide. When the low-k material is used as the interlayer dielectric layer IDL in the semiconductor devices SD, the insulating ability may be improved, and thus it may affect the implementation of high integration and/or high speed of the semiconductor devices SD.

In some implementations, the scribe lane region SR may include a dummy structure similar to the wiring structure WS. For example, the dummy structure disposed in the scribe lane region SR may include multilayer dummy wirings corresponding to the respective conductive wirings CDW together with the interlayer dielectric layer IDL and the insulating layers. In some implementations, the scribe lane region SR may include test patterns for testing the semiconductor devices SD in the chip regions CR and a redistribution layer for connection between the test patterns and may include an alignment key for alignment of a mask. In some implementations, the wafer WF may further include, on the frontside layer FL, a material layer having various functions, such as a passivation layer.

The backside layer BL may be disposed on the backside SUBb of the base layer SUB and may include at least one layer. In some implementations, the backside layer BL may include a layer having at least one of a silicon element (Si), a nitrogen element (N), or an oxygen element (O) as a component. For example, the backside layer BL may include an oxide layer, a nitride layer, an oxy nitride layer, a silicon layer, a silicon oxide layer, or a silicon oxy nitride layer.

Referring to FIGS. 1, 4, and 10, a protective sheet PRT may be laminated on the frontside WFa of the wafer WF. The protective sheet PRT serves to prevent a surface of the wafer WF from being damaged in a subsequent process. For example, the protective sheet PRT may prevent foreign matter from being attached to the upper side of the frontside layer FL. The protective sheet PRT may include a polymer resin, and the type of polymer resin is not particularly limited. The protective sheet PRT may be formed by forming a film of a thermosetting resin or curing the thermosetting resin. As another example, the protective sheet PRT may be formed by forming a film of a thermoplastic resin or curing the thermoplastic resin. In some implementations, the protective sheet PRT may be formed of a resin capable of ensuring adhesion to the wafer WF, prevention of penetration of foreign matter, and washability after semiconductor wafer cutting. For example, the protective sheet PRT may include an organic-soluble/non-aqueous-solvent-soluble resin or a water-soluble resin. The protective sheet PRT may be formed to have various thicknesses as needed.

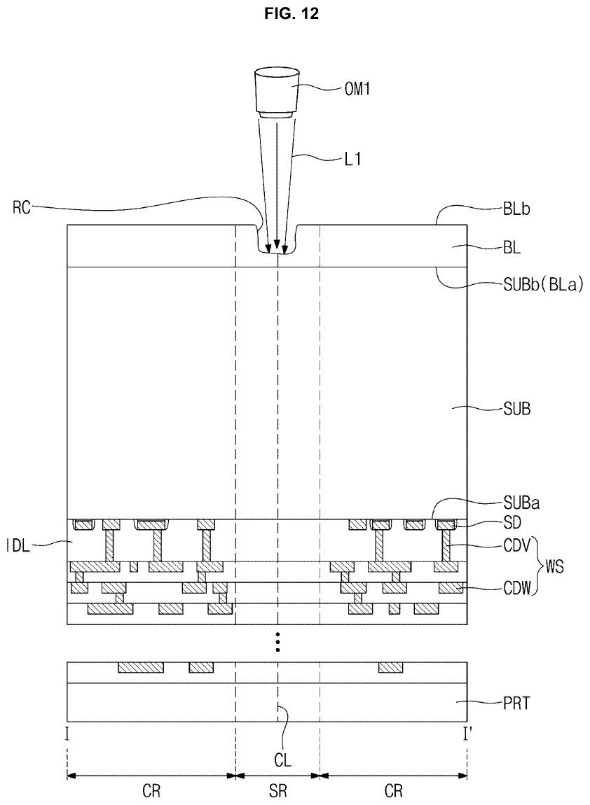

Referring to FIG. 12, a recess RC may be formed in the backside layer BL of the wafer WF. The recess RC may be formed in the scribe lane region SR. The recess RC may be formed along the cut line in the scribe lane region SR.

Referring to FIGS. 1 and 2, the emitting of the first laser beam onto the backside layer (S401) in the semiconductor device manufacturing method may include placing a first optical module in one scribe lane region (S411), providing a short-wavelength laser beam to the first optical module (S431), and forming the recess RC by emitting the first laser beam (S451).

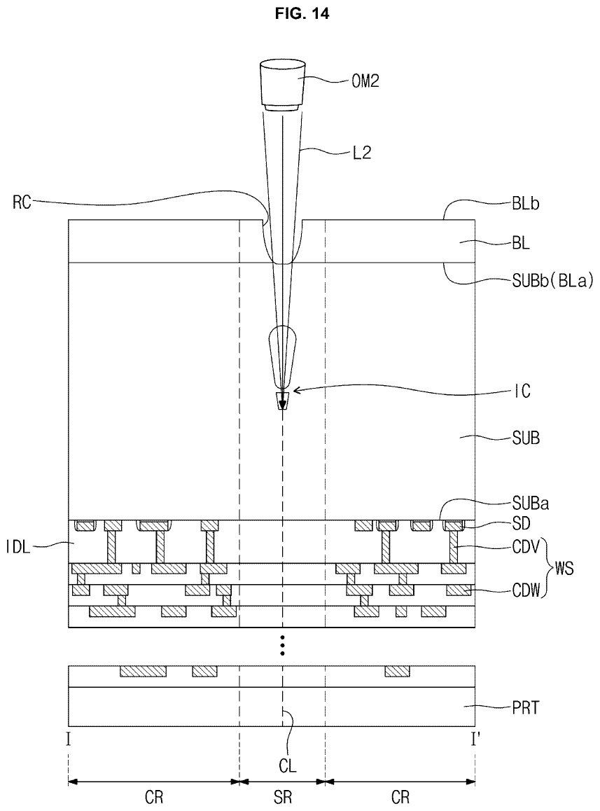

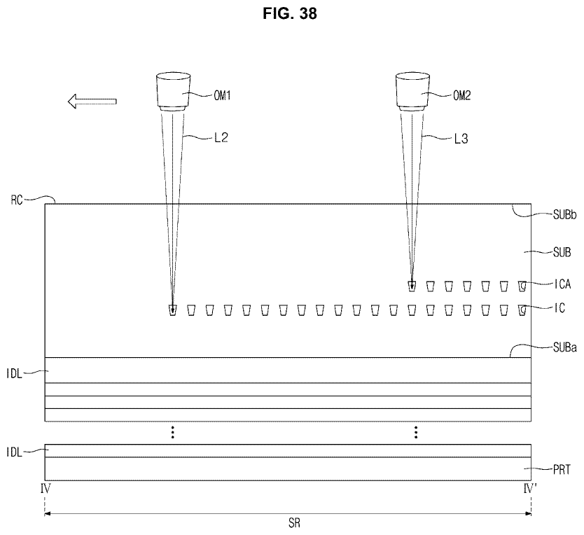

A laser beam may be repeatedly emitted with pulses lasting for a very short time. However, without being limited thereto, the laser beam may be continuously emitted. The laser beam may be applied to a target point of an object being processed, for example, the wafer WF to form the recess RC, an inner crack IC (shown in FIG. 14), or an additional inner crack ICA (shown in FIG. 38) by laser ablation. A focus generated by the laser beam may be formed on a surface of the object being processed or at a point close to the surface or may be formed at a specific point inside the object being processed. The focal spot of the laser beam may be located at the target point (e.g., on the surface of the wafer WF, at a certain depth from the surface of the wafer WF, or above the surface of the wafer WF). The focal spot of the laser beam may be moved in one direction on the surface of the object being processed. The direction of movement or the direction of emission may correspond to a cut line for cutting the object being processed.

When the laser beam is a pulse, the laser beam may be focused on a narrow region on the wafer WF and may be focused on a narrow region inside the wafer WF. In this case, the laser beam may have a high peak power density of about 1*10⁸ W/cm² in space (focusing) and time (pulsing) near the focus set inside the wafer WF. The laser beam having the high peak power density may cause a nonlinear absorption effect on the wafer WF near the focus. The laser beam transmitting through the surface of the wafer WF may be absorbed with a high absorption rate near the focus inside the wafer WF. Accordingly, the portion inside the wafer WF that absorbs the laser beam may have a high-density defect (e.g., dislocation), and thus a vertical crack may be easily formed inside the wafer WF.

The laser beam may have a laser power in the range of about 1 W to about 100 W or about 10 W to about 70 W, a laser pulse duration in the range of about 100 fs to about 500 ps or about 500 fs to about 500 ps, a laser pulse repetition rate in the range of about 10 kHz to about 2000 kHz, a nominal pulse energy in the range of about 50 μJ to about 300 μJ, a laser wavelength in the range of about 300 nm to about 1100 nm, and a laser scanning speed in the range of about 10 mm/s to about 3000 mm/s.

In some implementations, to reduce the occurrence of a heat affected zone, the laser beam may have the laser power in the range of about 30 W to about 70 W, the laser pulse duration in the range of about 200 fs to about 15 ps, the laser pulse repetition rate in the range of about 300 kHz to about 3 MHz, the nominal pulse energy in the range of about 80 μJ to about 200 μJ, the laser wavelength in the range of about 330 nm to about 600 nm, and the laser scanning speed in the range of about and 50 mm/s to about 2000 mm/s.

In some implementations, to reduce the occurrence of a heat affected zone, the laser beam may have the laser power in the range of about 0.1 W to about 30 W, the laser pulse duration in the range of about 500 fs to about 50 ps, the laser pulse repetition rate in the range of about 100 kHz to about 1000 kHz, the nominal pulse energy in the range of about 0.1 μJ to about 200 μJ, the laser wavelength in the range of about 330 nm to about 600 nm, and the laser scanning speed in the range of about and 50 mm/s to about 2000 mm/s.

In some implementations, the wavelength band of the laser beam may range from about 100 nm to about 600 nm. The pulse width of the laser beam may range from about 1 fs to about 1000 ns, for example, from about 1 fs to about 20 ps. The energy per pulse of the laser beam may range from about 0.1 uJ to about 50 uJ. In some implementations, the accumulated energy per unit area may range from about 0.1 J/m² to about 1000 J/m². The width of the laser beam may range from about 1 um to about 1000 um.

An optical module may be moved along the cut line in the scribe lane region SR of the wafer WF. For example, the optical module may be moved in horizontal directions (e.g., in directions parallel to the backside WFb of the wafer WF and perpendicular to each other) such that a laser is emitted along the scribe lane region SR. As another example, a stage having the wafer WF mounted thereon may be moved with the optical module fixed, such that a laser beam is emitted to the scribe lane region SR. As another example, the stage having the wafer WF mounted thereon and the optical module may be simultaneously moved such that a laser beam is emitted to the scribe lane region SR.

The optical module may include at least one lens and may focus a provided laser beam through the lens. The laser beam may be focused through the optical module and may be applied to the wafer WF that is an object being processed. In some implementations, the optical module may adjust the position of the at least one lens to control the point where the laser beam is focused. In some implementations, the optical module may include a first optical module OM1 and a second optical module OM2, as shown in FIG. 5. The first optical module OM1 may focus the laser beam onto a first focusing point. The second optical module OM2 may focus the laser beam onto a second focusing point. In this case, the first focusing point and the second focusing point may be different points. For example, the first focusing point may be one point in one scribe lane region, and the second focusing point may be another point in the one scribe lane region. For example, the first focusing point may be one point in one scribe lane region, and the second focusing point may be one point in another scribe lane region. For example, the first focusing point may be one point corresponding to a first position level in the base layer SUB of one scribe lane region, and the second focusing point may be one point corresponding to a second position level in the base layer SUB of the one scribe lane region. In this case, the first position level may be different from the second position level, and therefore the first focusing point may have a position level different from that of the second focusing point.

Referring to FIGS. 2, 5, 8, and 12, the first optical module OM1 may be disposed in (or above) the scribe lane region SR of the wafer WF and may be moved along the cut line CL in the scribe lane region SR of the wafer WF. In some implementations, the first optical module OM1 may be moved in horizontal directions such that the first laser beam L1 is emitted along the scribe lane region SR. For example, the first optical module OM1 may be moved in directions parallel to the backside WFb of the wafer WF and perpendicular to each other. As another example, the stage having the wafer WF mounted thereon may be moved with the first optical module OM1 fixed, such that the first laser beam L1 is emitted to the scribe lane region SR. As another example, the stage having the wafer WF mounted thereon and the first optical module OM1 may be simultaneously moved such that the first laser beam L1 is emitted to the scribe lane region SR. In some implementations, the first laser beam L1 may be a laser beam that forms the recess RC. In addition, the first laser beam L1 may include short-wavelength laser beams passing through the first optical module OM1 and/or the second optical module OM2.

Referring to FIGS. 2, 5, 8, 12, and 13, in some implementations, the recess RC may be formed by the first laser beam L1 emitted onto the wafer WF. In this case, the process of forming the recess RC by emitting the first laser beam L1 may be referred to as a dicing step. The dicing step may be a step of removing only a portion of the wafer WF and may be referred to as a half dicing step.

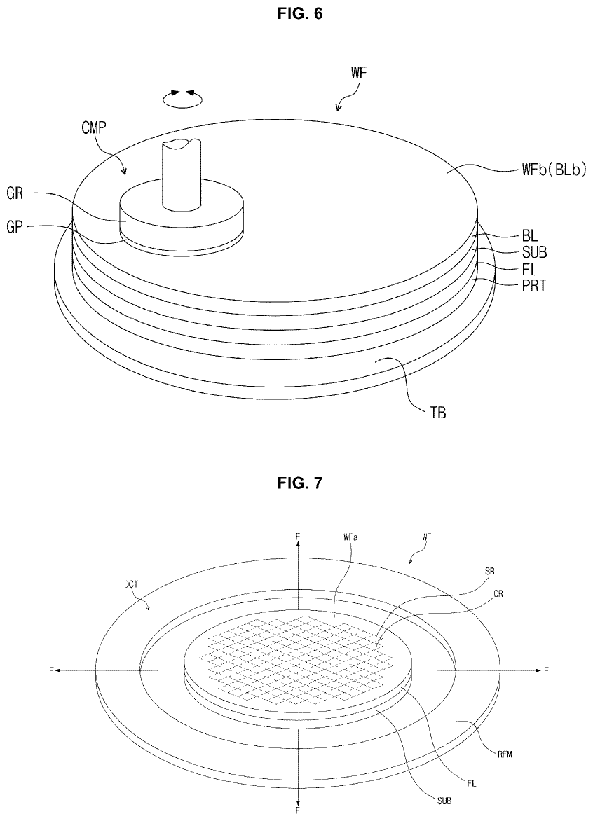

The recess RC may be formed by the first laser beam L1. The recess RC may be formed through a portion of the backside layer BL, the backside layer BL, and/or at least a portion of the wafer WF in a direction from the backside BLb to the frontside BLa of the backside layer BL. The backside WFb (labeled in FIG. 6) of the wafer WF may be partially exposed through the recess RC. The recess RC may be disposed adjacent to the backside WFb of the wafer WF. For example, the first optical module OM1 may emit the first laser beam L1 to a position adjacent to the backside WFb of the wafer WF. Through the dicing step, a portion of the backside layer BL may be removed, the backside layer BL may be removed, or the backside layer BL and at least a portion of the wafer WF may be removed.

Referring to FIGS. 1 and 2, the emitting of the second laser beam (S402) in the semiconductor device manufacturing method may include placing the second optical module in the one scribe lane region (S412), providing a long-wavelength laser beam to the second optical module (S432), and forming an inner crack by emitting the second laser beam (S452).

Referring to FIGS. 2, 5, 8, and 14, the second optical module OM2 may be disposed in the scribe lane region SR of the wafer WF and may be moved along the cut line CL in the scribe lane region SR of the wafer WF. In some implementations, the second optical module OM2 may be moved in the horizontal directions such that the second laser beam L2 is emitted along the scribe lane region SR. For example, the second optical module OM2 may be moved in the directions parallel to the backside WFb of the wafer WF and perpendicular to each other. As another example, the stage having the wafer WF mounted thereon may be moved with the second optical module OM2 fixed, such that the second laser beam L2 is emitted to the scribe lane region SR. As another example, the stage having the wafer WF mounted thereon and the second optical module OM2 may be simultaneously moved such that the second laser beam L2 is emitted to the scribe lane region SR. In some implementations, the second laser beam L2 may be a laser beam that forms the inner crack IC. In addition, the second laser beam L2 may include long-wavelength laser beams passing through the first optical module OM1 and/or the second optical module OM2. In some implementations, the focusing point of the second optical module OM2 may be different from the focusing point of the first optical module OM1.

Referring to FIGS. 2, 5, 8, 14, and 15, in some implementations, the inner crack IC may be formed by the second laser beam L2 emitted onto the wafer WF. In this case, the process of forming the inner crack IC by emitting the second laser beam L2 may be referred to as a stealth dicing step or a reformed-pattern forming step.

The inner crack IC may be formed by the second laser beam L2. In some implementations, the inner crack IC may be formed in the scribe lane region SR of the wafer WF. For example, the inner crack IC may vertically overlap the recess RC. The inner crack IC and the recess RC may be vertically spaced apart from each other. In some implementations, the inner crack IC may have a conical shape that is wider in the vertical direction than in the horizontal direction.

Referring to FIGS. 1, 6, 15, and 17, the backside WFb of the wafer WF and the backside layer BL may be polished. Polishing may be performed by a polishing apparatus CMP.

The wafer WF having the protective sheet PRT attached to the frontside WFa thereof may be arranged such that the backside WFb of the wafer WF faces upward and may be placed on a chuck table TB. The backside WFb of the wafer WF may be the backside BLb of the backside layer BL and may correspond to an inactive side.

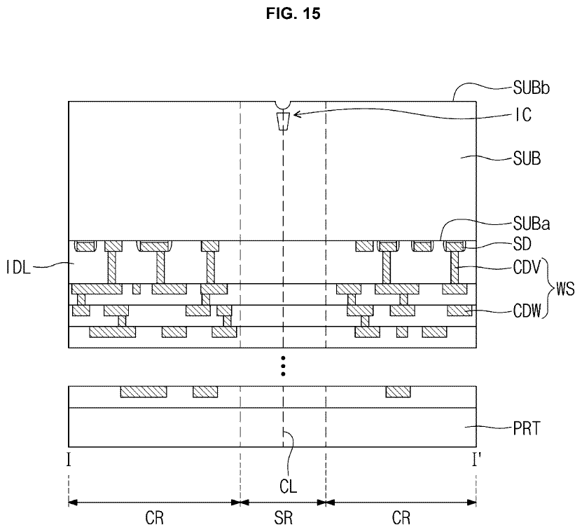

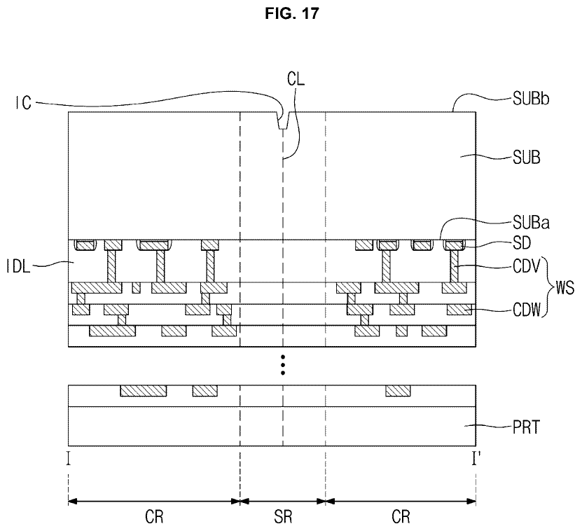

By polishing the backside WFb of the wafer WF and the backside layer BL, the backside layer BL on the backside WFb of the wafer WF may be removed, and the thickness of the base layer SUB within the wafer WF may be reduced. As illustrated in FIGS. 15 and 17, the thickness of the base layer SUB may be adjusted as needed.

The polishing apparatus CMP, as shown in FIG. 6, may include a chuck table TB that supports the base layer SUB and a grinder GR that polishes the base layer SUB disposed on the chuck table TB and the backside layer BL on the base layer SUB. The grinder GR may move while rotating, and a polishing pad GP may be attached to the bottom of the grinder GR.

The polishing process may be a grinding process in a state in which physical pressure is applied to the base layer SUB. The polished base layer SUB may have a smaller thickness after being polished than before being polished. In some implementations, the inner crack IC may be easily propagated through the grinding process. At least a portion of the inner crack IC may be propagated toward the backside SUBb of the base layer SUB in the polishing process. However, the inner crack IC may not be propagated in the polishing process and may instead or additionally occur in a dicing tape expansion step to be described below.

Referring to FIGS. 1 and 7, the wafer WF may be mounted on a dicing tape DCT. The wafer WF may be inverted such that the frontside WFa to which the protective sheet PRT is attached faces upward and may be mounted on the dicing tape DCT. In some implementations, the backside WFb of the wafer WF may be attached to the dicing tape DCT. In some implementations, an adhesive film may be attached to the backside WFb of the wafer WF. The adhesive film may serve to support the wafer WF and may facilitate handling of the wafer WF later. The adhesive film may be provided on the backside WFb of the wafer WF before the wafer WF is attached to the dicing tape DCT. In this case, the wafer WF may be attached to the dicing tape DCT with the adhesive film therebetween.

The protective sheet PRT may be removed after the wafer WF is mounted on the dicing tape DCT. The protective sheet PRT may be delaminated by a film delamination apparatus or may be removed by a wet cleaning process. The wet cleaning process may be performed using an organic solvent or an inorganic solvent depending on the material of the protective sheet PRT.

The dicing tape DCT may be supported and fixed by a ring frame RFM attached to one side thereof. Thereafter, an external force F may be applied to the dicing tape DCT to expand the dicing tape DCT such that the semiconductor chips are separated from the wafer WF. The dicing tape DCT may be radially expanded as illustrated.

In some implementations, the dicing tape DCT may be placed on a jig and may be expanded by pushing the jig upward. In some implementations, heat may be applied to the dicing tape DCT, and the dicing tape DCT may be expanded by heating the dicing tape DCT with the heat.

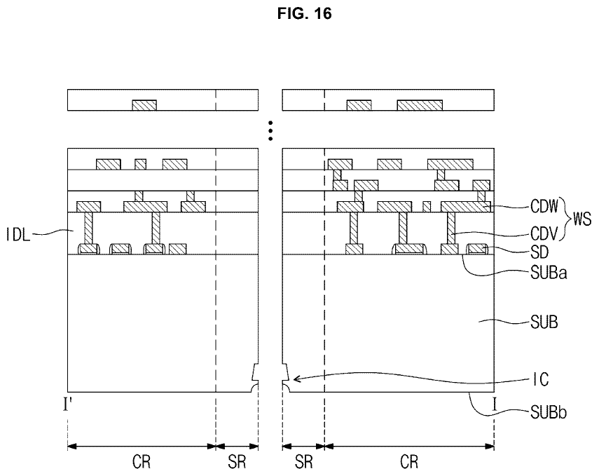

By expanding the dicing tape DCT, the wafer WF may be cut into the individual semiconductor chips along the scribe lane region SR, as shown in FIG. 16. When the dicing tape DCT is expanded while the wafer WF is disposed on the dicing tape DCT, the base layer SUB may be subject to brittle fracture. The brittle fracture refers to the destruction of an object without permanent deformation when a force exceeding an elastic limit is applied to the object. The base layer SUB may be subject to brittle failure by the inner crack IC. The inner crack IC may be propagated toward the backside SUBb of the base layer SUB as the dicing tape DCT is expanded. As the inner crack IC is expanded along the scribe lane region SR that isolates the chip regions CR from one another, the chip regions CR may be separated into the semiconductor chips by the brittle fracture of the base layer SUB. Each of the semiconductor chips may be picked up and transmitted to a separate support substrate by a different process apparatus. The support substrate may be a temporary carrier that supports and fixes the semiconductor chip before a die attach process is performed.

When the dicing tape DCT is expanded to apply the tension of the tape to the wafer WF, the expansion speed of the dicing tape DCT may range from about 1 mm/s to about 1000 mm/s. For example, the expansion speed of the dicing tape DCT may be about 5 mm/s or more or about 10 mm/s or more. The expansion length of the dicing tape DCT in one direction may range from about 0.1 mm to about 100 mm or from about 0.1 mm to about 30 mm, for example, from about 1 mm to about 20 mm.

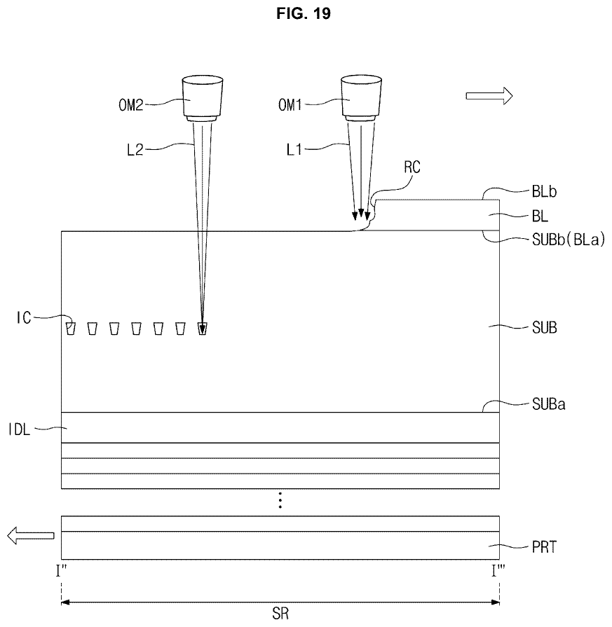

FIGS. 19, 21, and 23 are sectional views taken along line I′′-I′′′ of FIG. 8.

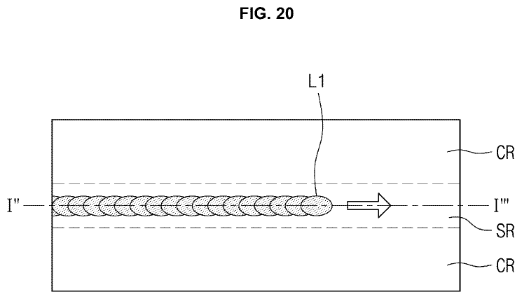

FIGS. 20, 22, and 24 are plan views showing an enlarged view of line I′′-I′′′ of FIG. 8.

Referring to FIGS. 19 to 24, the first laser beam L1 and the second laser beam L2 may be emitted onto the wafer WF along the direction of movement of the first optical module OM1 and the second optical module OM2. The first laser beam L1 and the second laser beam L2 may be emitted along the cut line CL in the scribe lane region SR. The cut line CL may be a virtual line along which cutting is performed.

In some implementations, the first optical module OM1 may move along the direction of emission, and the second optical module OM2 may move along the movement path of the first optical module OM1. Accordingly, the recess RC having a size corresponding to the width of the first laser beam L1 may first be formed on the wafer WF. Then, the second laser beam L2 following the first laser beam L1 may be emitted along the direction of movement of the first laser beam L1, and the inner crack IC may be formed inside the wafer WF. Since the second laser beam L2 is provided after the first laser beam L1, the recess RC may first be formed on the wafer WF, and the inner crack IC may be formed inside the wafer WF to vertically overlap the recess RC.

In some implementations, an emission mode in the semiconductor device manufacturing method may include a first mode for sequentially emitting laser beams and/or a second mode for simultaneously emitting at least some of the laser beams.

The first mode may be a mode in which, among n laser beams, preceding laser beams are completely emitted and then following laser beams are emitted. For example, in the first mode, the second laser beam L2 may be emitted after the first laser beam L1 is completely emitted. Here, the first mode may be performed within a plurality of scans, and one laser beam may be provided per scan. For example, one laser beam among the n laser beams may be emitted in one scan. Each of the n laser beams may be emitted a plurality of times. In some implementations, the first laser beam L1 may be emitted a plurality of times, and the second laser beam L2 may also be emitted a plurality of times. For example, each of the first laser beam L1 and the second laser beam L2 may be emitted once. For example, each of the first laser beam L1 and the second laser beam L2 may be emitted a plurality of times, and the first laser beam L1 and the second laser beam L2 may be alternately emitted. For example, the second laser beam L2 may be emitted a plurality of times after the first laser beam L1 is emitted a plurality of times.

The second mode may be a mode in which the n laser beams are emitted in one scan. For example, in the second mode, the emission of the first laser beam L1 and the emission of the second laser beam L2 may be included in one scan. In some implementations, the first laser beam L1 and the second laser beam L2 may be emitted in substantially the same time period. In the second mode, the emission may be repeated a plurality of times. Since the second mode includes a case in which the second laser beam L2 continuously follows the point where the first laser beam L1 is emitted, the second mode may include the emission method illustrated in FIGS. 5 and 19.

Referring to FIGS. 1, 2, 5, 12, 14, and 19, at least a portion of the emission of the first laser beam onto the backside layer (S401) and at least a portion of the emission of the second laser beam onto the backside layer may be simultaneously performed. For example, the providing of the short-wavelength laser beam to the first optical module (S431) and the providing of the long-wavelength laser beam to the second optical module (S432) may be simultaneously performed, and the forming of the recess by emitting the first laser beam (S451) and the forming of the inner crack by emitting the second laser beam (S452) may be simultaneously performed. In this case, the first optical module OM1 may have a focusing point different from the focusing point of the second optical module OM2, and the second optical module OM2 may be spaced apart from the first optical module OM1 and may continuously follow the movement path of the first optical module OM1. Accordingly, the first laser beam L1 and the second laser beam L2 may be simultaneously emitted in terms of time and may be emitted to different points in terms of space. In some implementations, the recess RC may be formed by the first laser beam L1, and the second laser beam L2 may be emitted into the recess RC to form the inner crack IC in the base layer SUB. In this case, the recess RC and the inner crack IC may vertically overlap each other.

Referring to FIGS. 19 and 20, the first laser beam L1 may penetrate the backside layer BL and a portion of the base layer SUB to form the recess RC. For example, in the region to which the first laser beam L1 is emitted, all of the backside layer BL may be etched, and a portion of the backside SUBa of the base layer SUB may be etched. When the first laser beam L1 is continuously emitted, in the region to which the first laser beam L1 is emitted, the recess RC may be formed to be continuous along the direction of emission in the scribe lane region SR. When the first laser beam L1 is discontinuously emitted, the first laser beam L1 may be emitted such that the regions to which the first laser beam L1 is emitted partially overlap each other. Accordingly, even when the first laser beam L1 is a pulse, the recess RC may be formed to be continuous. Accordingly, in some implementations the recess RC may have a groove shape in a planar view.

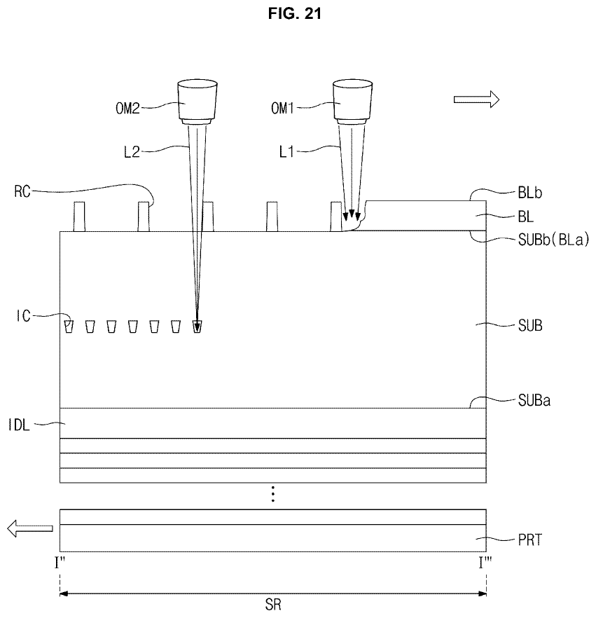

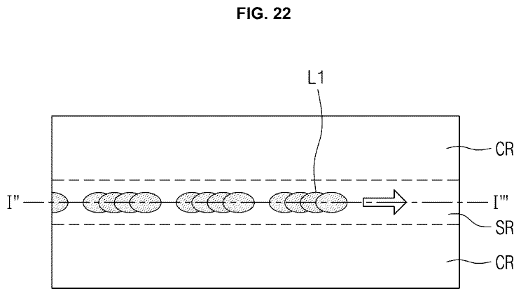

Referring to FIGS. 21 and 22, the first laser beam L1 may penetrate the backside layer BL to form recesses RC. In this case, regions to which the first laser beam L1 is not emitted may exist, and therefore the recesses RC may be spaced apart from each other. When the first laser beam L1 is continuously emitted, in the region to which the first laser beam L1 is emitted, the recess RC may be formed to be continuous along the direction of emission in the scribe lane region SR. In this case, the first laser beam L1 may be partially turned off, and therefore the continuous recesses RC may be spaced apart from each other. When the first laser beam L1 is discontinuously emitted, the first laser beam L1 may be emitted such that the regions to which the first laser beam L1 is emitted partially overlap each other. Accordingly, even when the first laser beam L1 is a pulse, continuous recesses RC may be formed. The continuous recesses RC may be spaced apart from each other. Accordingly, in some implementations, the recesses RC may have a bar shape in a planar view.

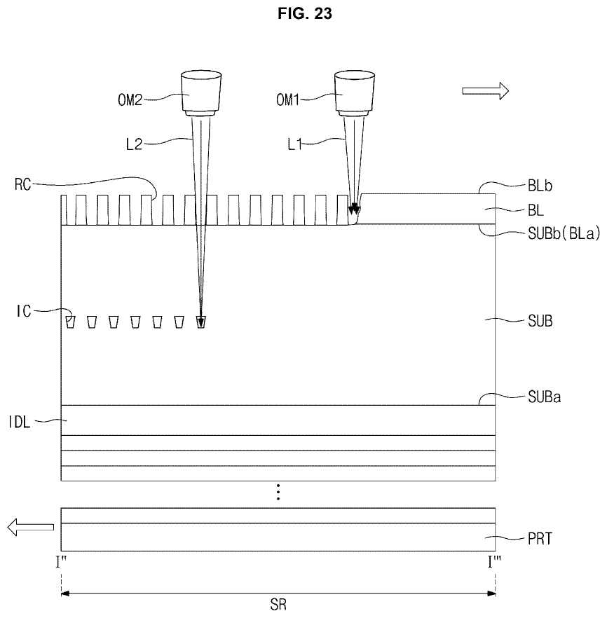

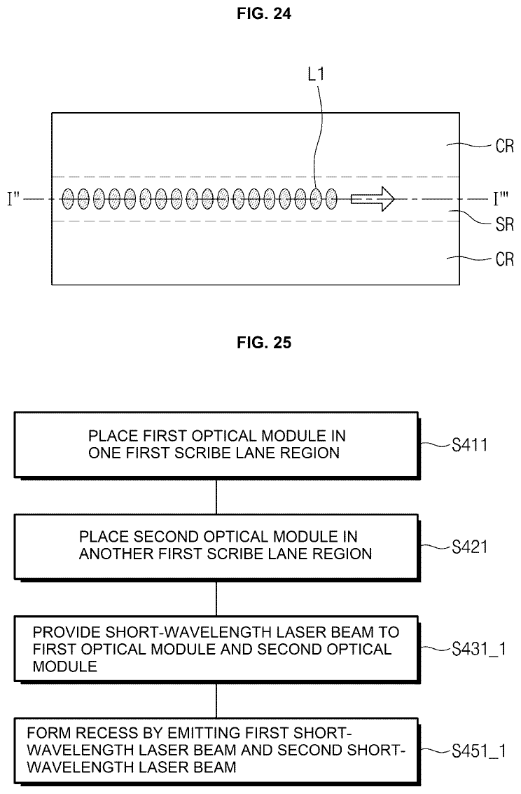

Referring to FIGS. 23 and 24, the first laser beam L1 may penetrate the backside layer BL to form recesses RC. In this case, regions to which the first laser beam L1 is not emitted may exist, and therefore the recesses RC may be spaced apart from each other. The first laser beam L1 may be emitted such that the regions to which the first laser beam L1 is emitted are spaced apart from each other, and thus the recesses RC may be spaced apart from each other. Accordingly, in some implementations, the recesses RC may have a dot shape in a planar view.

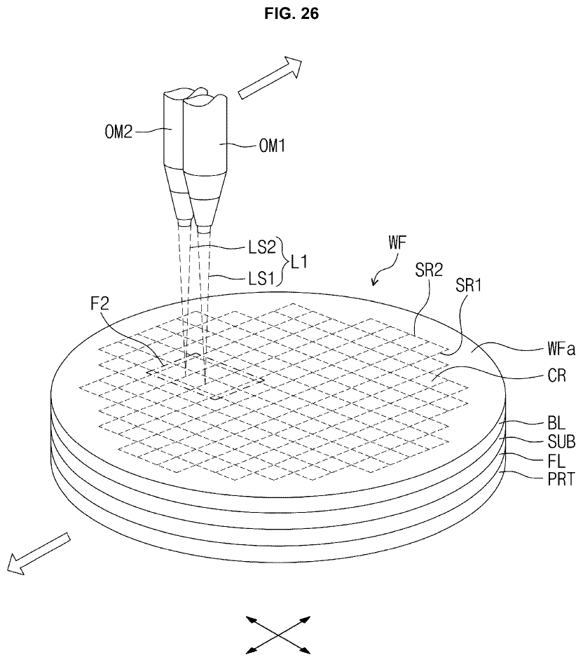

FIGS. 25, 30, 34, 35, 39, 43, and 46 are flowcharts illustrating examples of semiconductor device manufacturing methods. FIGS. 26, 31, 36, 40, 44, and 47 are schematic perspective diagrams illustrating the semiconductor device manufacturing methods.

Referring to FIGS. 1, 2, and 25, the emitting of the first laser beam (S401) in the semiconductor device manufacturing method may include placing the first optical module in one first scribe lane region (S411), placing the second optical module in another first scribe lane region (S421), providing a short-wavelength laser beam to the first optical module and the second optical module (S431_1), and forming recesses RC by emitting a first short-wavelength laser beam and a second short-wavelength laser beam (S451_1).

Referring to FIGS. 25 and 26, the first optical module OM1 may be disposed in one scribe lane region SR, and the second optical module OM2 may be disposed in another scribe lane region SR. In this case, the first optical module OM1 and the second optical module OM2 may be disposed spaced apart from one another in a direction perpendicular to the illustrated direction of movement. For example, the first optical module OM1 and the second optical module OM2 may be disposed side by side. For example, the first optical module OM1 and the second optical module OM2 may be arranged to emit laser beams to different rows or columns of the scribe lane region SR. In some implementations, the short-wavelength laser beam may be provided to the first optical module OM1 and the second optical module OM2. Since the short-wavelength laser beam is provided to the first optical module OM1 and the second optical module OM2, the first short-wavelength laser beam LS1 and the second short-wavelength laser beam LS2 may be emitted onto the backside WFb of the wafer WF. In some implementations, the short-wavelength laser beam may be provided from at least one laser beam source. For example, the short-wavelength laser beam may be provided from one laser beam source and may be provided to the first optical module OM1 and the second optical module OM2. For example, the short-wavelength laser beams may be provided from laser beam sources, respectively, and may be provided to the first optical module OM1 and the second optical module OM2, respectively. In some implementations, the first laser beam L1 may include the first short-wavelength laser beam LS1 and the second short-wavelength laser beam LS2. In some implementations, the first optical module OM1 and the second optical module OM2 may have focusing points corresponding to position levels that are equal or similar to each other.

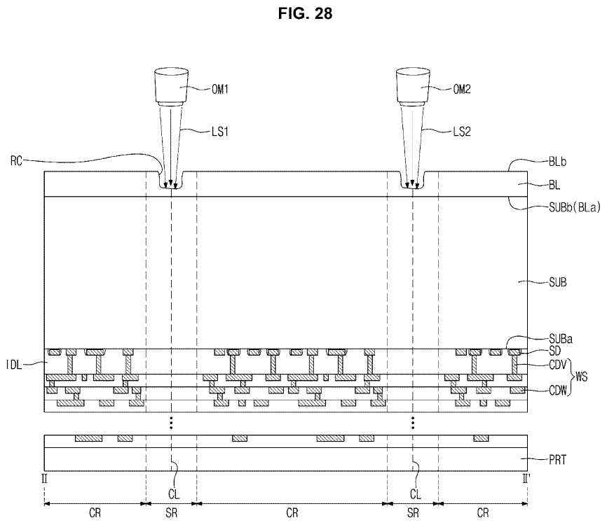

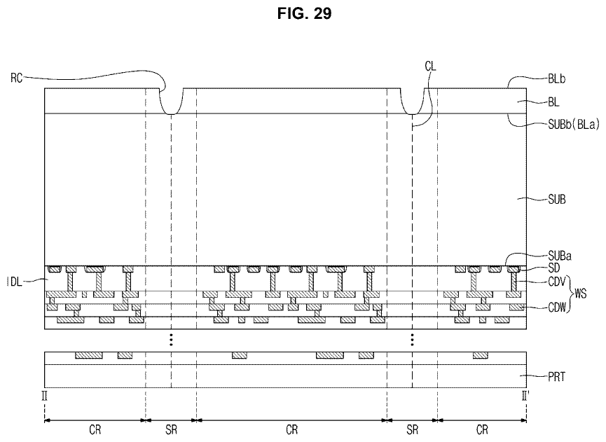

FIG. 27 is a plan view corresponding to ‘F2’ of FIG. 26. FIGS. 28 and 29 are sectional views taken along line II-II′ of FIG. 27.

Referring to FIGS. 25 to 29, the first short-wavelength laser beam LS1 and the second short-wavelength laser beam LS2 may etch portions of the backside layer BL and may etch the backside layer BL and/or portions of the wafer WF. For example, the first short-wavelength laser beam LS1 and the second short-wavelength laser beam LS2 may form the recesses RC in the backside layer BL of the wafer WF. The recesses RC may be formed in the scribe lane region SR. The recesses RC may be formed along the cut lines in the scribe lane region SR. In some implementations, the first short-wavelength laser beam LS1 and the second short-wavelength laser beam LS2 may flatten the backside WFb of the wafer WF or the backside layer BL.

In some implementations, the first laser beam L1 may include the first short-wavelength laser beam LS1 and the second short-wavelength laser beam LS2. In this case, the first short-wavelength laser beam LS1 may be a laser beam that passes through the first optical module OM1 and forms the recess RC, and the second short-wavelength laser beam LS2 may be a laser beam that passes through the second optical module OM2 and forms the recess RC.

Referring to FIGS. 1, 2, and 30, the emitting of the second laser beam (S402) in the semiconductor device manufacturing method may include placing the first optical module in one first scribe lane region (S412_1), placing the second optical module in another first scribe lane region (S422), providing a long-wavelength laser beam to the first optical module and the second optical module (S432_1), and forming inner cracks by emitting a first long-wavelength laser beam and a second long-wavelength laser beam (S452_1).

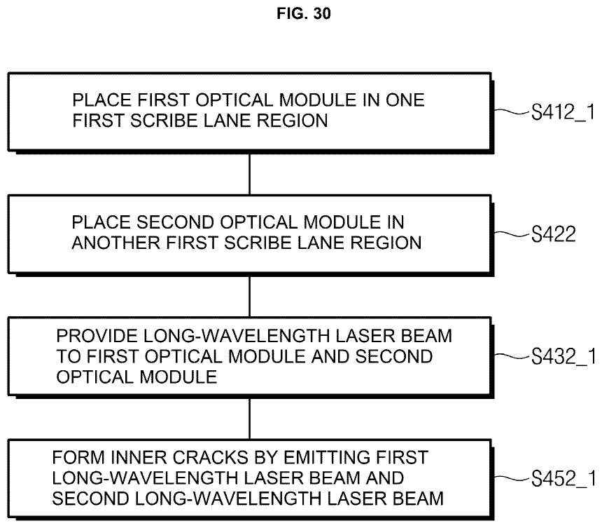

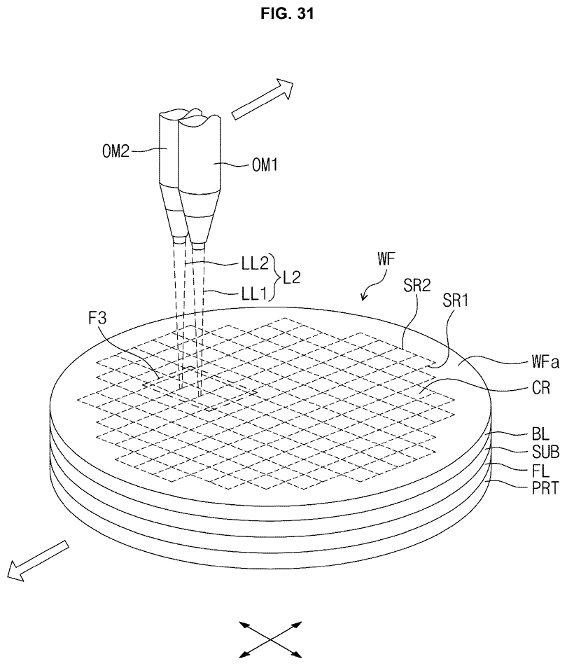

Referring to FIGS. 30 and 31, the first optical module OM1 may be disposed in one scribe lane region SR, and the second optical module OM2 may be disposed in another scribe lane region SR. In this case, the first optical module OM1 and the second optical module OM2 may be disposed spaced apart from one another in a direction perpendicular to the illustrated direction of movement. For example, the first optical module OM1 and the second optical module OM2 may be disposed side by side. For example, the first optical module OM1 and the second optical module OM2 may be arranged to emit laser beams to different rows or columns of the scribe lane region SR. In some implementations, the long-wavelength laser beam may be provided to the first optical module OM1 and the second optical module OM2. Since the long-wavelength laser beam is provided to the first optical module OM1 and the second optical module OM2, the first long-wavelength laser beam LL1 and the second long-wavelength laser beam LL2 may be emitted onto the backside WFb of the wafer WF. However, since the focuses of the first long-wavelength laser beam LL1 and the second long-wavelength laser beam LL2 are set inside the wafer WF, the first long-wavelength laser beam LL1 and the second long-wavelength laser beam LL2 may not etch a portion of the backside WFb of the wafer WF or the backside layer BL and may etch a very small portion of the backside WFb of the wafer WF or the backside layer BL. In some implementations, the first optical module OM1 and the second optical module OM2 may have focusing points corresponding to position levels that are equal or similar to each other.

In some implementations, the long-wavelength laser beam may be provided from at least one laser beam source. For example, the long-wavelength laser beam may be provided from one laser beam source and may be provided to the first optical module OM1 and the second optical module OM2. For example, the long-wavelength laser beams may be provided from laser beam sources, respectively, and may be provided to the first optical module OM1 and the second optical module OM2, respectively. In some implementations, the second laser beam L2 may include the first long-wavelength laser beam LL1 and the second long-wavelength laser beam LL2.

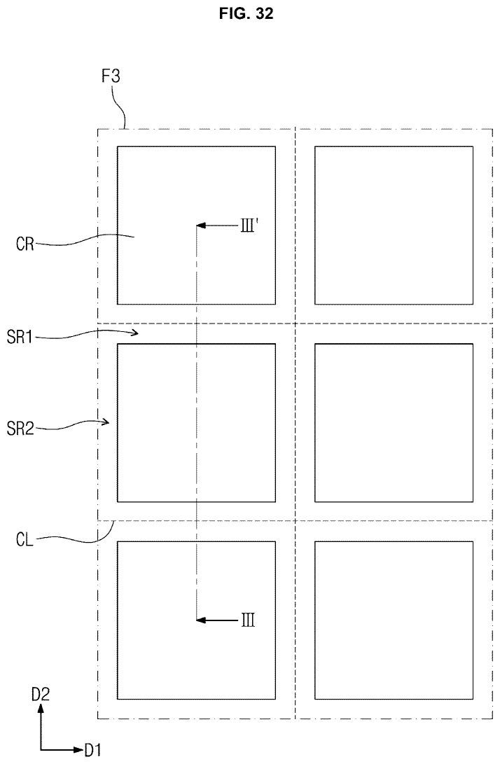

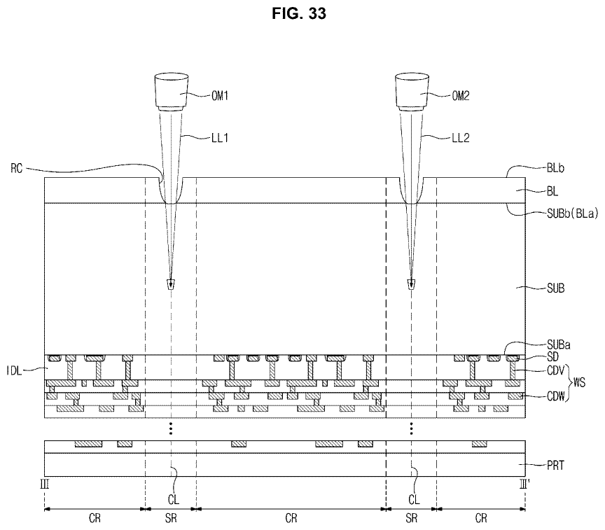

FIG. 32 is a plan view corresponding to ‘F3’ of FIG. 31. FIG. 33 is a sectional view taken along line III-III′ of FIG. 31.

Referring to FIGS. 30 to 33, the first long-wavelength laser beam LL1 and the second long-wavelength laser beam LL2 may etch a portion inside the wafer WF. In some implementations, the first long-wavelength laser beam LL1 and the second long-wavelength laser beam LL2 may etch a portion in the base layer SUB. For example, the first long-wavelength laser beam LL1 and the second long-wavelength laser beam LL2 may form the inner cracks IC in the base layer SUB. The inner cracks IC may be formed in the scribe lane region SR of the wafer WF. The inner cracks IC may be formed along the cut lines CL of the scribe lane region SR. For example, the inner cracks IC may vertically overlap the recesses RC. The inner cracks IC and the recesses RC may be vertically spaced apart from each other. In some implementations, the inner cracks IC may have a conical shape that is wider in the vertical direction than in the horizontal direction.

In some implementations, the second laser beam L2 may include the first long-wavelength laser beam LL1 and the second long-wavelength laser beam LL2. In this case, the first long-wavelength laser beam LL1 may be a laser beam that passes through the first optical module OM1 and forms the inner cracks IC, and the second long-wavelength laser beam LL2 may be a laser beam that passes through the second optical module OM2 and forms the inner cracks IC.

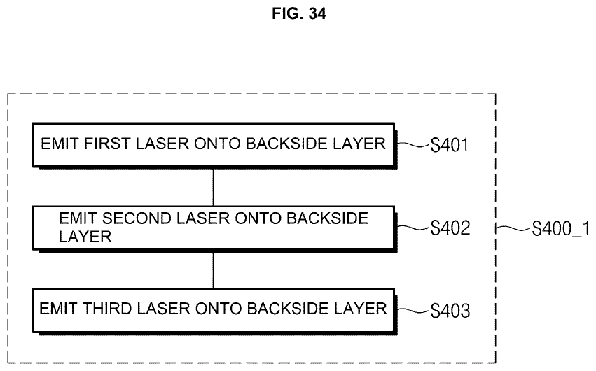

Referring to FIGS. 1 and 34, the semiconductor device manufacturing method may further include emitting a third laser beam onto the backside layer (S403). In this case, emitting a laser beam onto the backside layer (S400_1) may include emitting the first laser beam onto the backside layer (S401), emitting the second laser beam onto the backside layer (S402), and emitting the third laser beam onto the backside layer (S403).

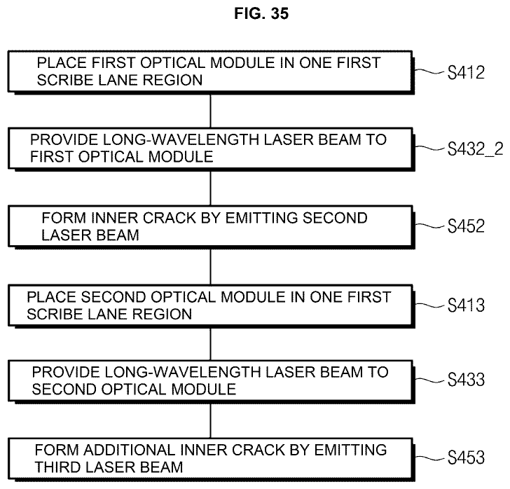

Referring to FIG. 35, the emitting of the second laser beam (S402) and the emitting of the third laser beam (S403) in the semiconductor device manufacturing method may include placing the first optical module in one first scribe lane region (S412), providing a long-wavelength laser beam to the first optical module (S432_1), forming an inner crack by emitting the second laser beam (S452), placing the second optical module in the one first scribe lane region (S413), providing a long-wavelength laser beam to the second optical module (S433), and forming an additional inner crack by emitting the third laser beam (S453).

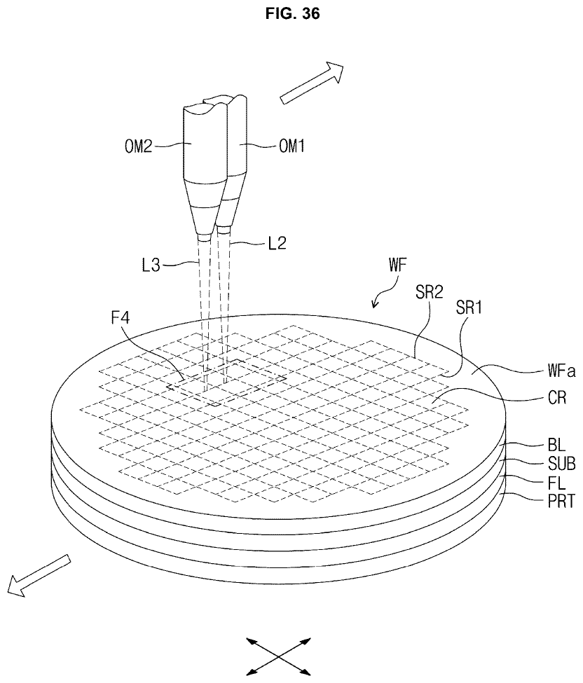

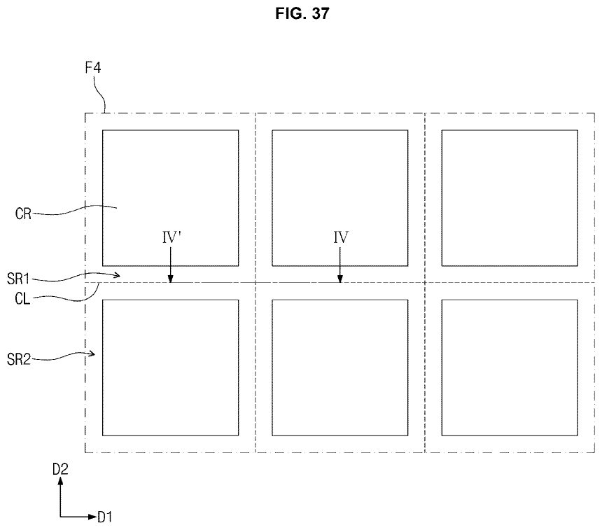

FIG. 37 is a plan view corresponding to ‘F4’ of FIG. 36. FIG. 38 is a sectional view taken along line IV-IV′ of FIG. 37.

Referring to FIGS. 35 and 36 to 38, the first optical module OM1 and the second optical module OM2 may be disposed in the first scribe lane region SR1 of the wafer WF and may be moved along the cut line CL in the first scribe lane region SR1. In some implementations, the first optical module OM1 and the second optical module OM2 may be moved in a horizontal direction such that the laser beams are emitted along the first scribe lane region SR1. For example, the first optical module OM1 and the second optical module OM2 may be moved in the directions parallel to the backside WFb of the wafer WF and perpendicular to each other. In some implementations, the stage having the wafer WF mounted thereon may be moved with the first optical module OM1 and the second optical module OM2 fixed, such that the second laser beam L2 and the third laser beam L3 are emitted to the first scribe lane region SR1. In some implementations, the stage having the wafer WF mounted thereon, the second optical module OM1, and the second optical module OM2 may be simultaneously moved such that the second laser beam L2 and the third laser beam L3 are emitted to the first scribe lane region SR1. In some implementations, the focusing point of the second optical module OM2 may be different from the focusing point of the first optical module OM1. In some implementations, the third laser beam L3 may have a wavelength that is the same as, or similar to, that of the second laser beam L2.

In some implementations, the second laser beam L2 may be a laser beam that forms the inner crack IC. In addition, the second laser beam L2 may include long-wavelength laser beams passing through the first optical module OM1 and the second optical module OM2. In some implementations, the inner crack IC may be formed by the second laser beam L2 emitted onto the wafer WF. In this case, the second laser beam L2 may be emitted in a direction from the backside SUBb to the frontside SUBa through the backside SUBb of the base layer SUB because the backside layer BL of the wafer WF has been etched through the previous process. In some implementations, only a portion of the backside layer BL may be etched so that the remaining portion of the backside layer BL may be disposed on the backside SUBb of the base layer SUB, and the second laser beam L2 may be emitted in the direction from the backside BLb to the frontside BLa through the backside BLb of the backside layer BL.

In some implementations, the third laser beam L3 may be a laser beam that forms the additional inner crack ICA. In addition, the third laser beam L3 may include long-wavelength laser beams passing through the first optical module OM1 and/or the second optical module OM2. In some implementations, the additional inner crack ICA may be formed by the third laser beam L3 emitted onto the wafer WF. In this case, the third laser beam L3 may be emitted in the direction from the backside SUBb to the frontside SUBa through the backside SUBb of the base layer SUB because the backside layer BL of the wafer WF has been etched through the previous process. However, only a portion of the backside layer BL may be etched so that the remaining portion of the backside layer BL may be disposed on the backside SUBb of the base layer SUB, and the third laser beam L3 may be emitted in the direction from the backside BLb to the frontside BLa through the backside BLb of the backside layer BL.

The additional inner crack ICA may be formed by the third laser beam L3. In some implementations, the additional inner crack ICA may be formed in the scribe lane region SR of the wafer WF. For example, the additional inner crack ICA may vertically overlap the inner crack IC. In this case, the additional inner crack ICA and the inner crack IC may be vertically spaced apart from each other. In some implementations, the additional inner crack ICA may have a conical shape that is wider in the vertical direction than in the horizontal direction. In addition, the additional inner crack ICA may have a shape that is the same as, or similar to, that of the inner crack IC. The shape of the additional inner crack ICA is not limited thereto, and the additional inner crack ICA may have a shape different from the shape of the inner crack IC. In some implementations, the additional inner crack ICA may include additional inner cracks having different position levels. For example, the additional inner crack ICA may include a first additional inner crack and a second additional inner crack, and the first additional inner crack and the second additional inner crack may have different position levels.

Referring to FIGS. 1, 2, 19, 34, 35, 36, and 38, at least a portion of the emission of the second laser beam onto the backside layer (S402) and at least a portion of the emission of the third laser beam onto the backside layer may be simultaneously performed. For example, the providing of the long-wavelength laser beam to the first optical module (S432_2) and the providing of the long-wavelength laser beam to the second optical module (S433) may be simultaneously performed, and the forming of the inner crack by emitting the second laser beam (S452) and the forming of the additional inner crack by emitting the third laser beam (S453) may be simultaneously performed. In this case, the first optical module OM1 may have a focusing point different from the focusing point of the second optical module OM2, and the second optical module OM2 may be spaced apart from the first optical module OM1 and may continuously follow the movement path of the first optical module OM1. Accordingly, the second laser beam L2 and the third laser beam L3 may be simultaneously emitted in terms of time and may be emitted to different points in terms of space. In some implementations, the second laser beam L2 may be emitted to form the inner crack IC in the base layer SUB, and the third laser beam L3 may be emitted to form the additional inner crack ICA in the base layer SUB. In this case, the inner crack IC and the additional inner crack ICA may vertically overlap each other.

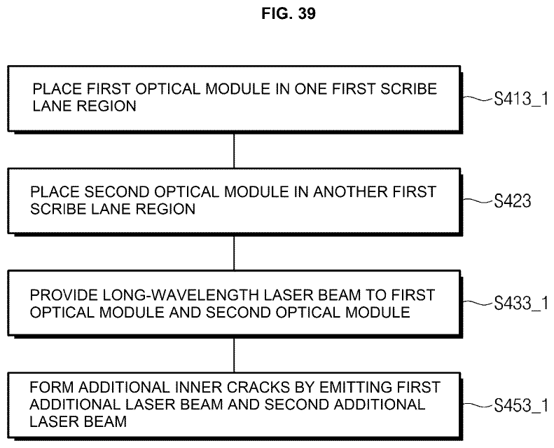

Referring to FIGS. 34 and 39, the emitting of the third laser beam onto the backside layer (S403) in the semiconductor device manufacturing method may include placing the first optical module in one first scribe lane region (S413_1), placing the second optical module in another first scribe lane region (S423), providing a long-wavelength laser beam to the first optical module and the second optical module (S433_1), and forming additional inner cracks by emitting a first additional laser beam and a second additional laser beam (S453_1).

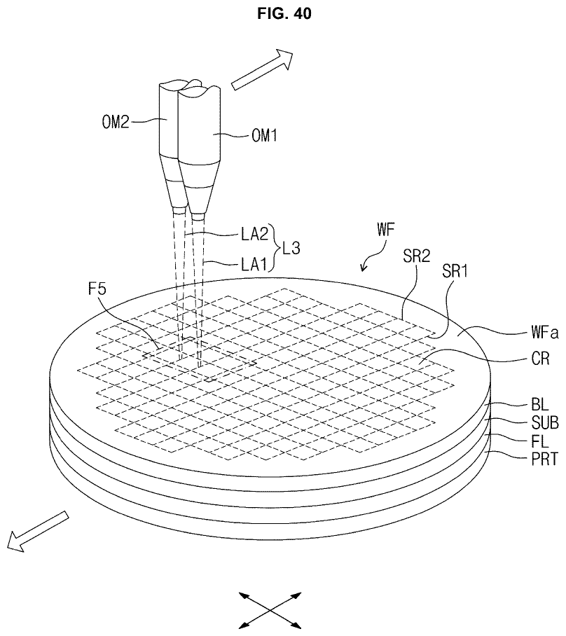

Referring to FIGS. 39 and 40, the first optical module OM1 may be disposed in one first scribe lane region SR1, and the second optical module OM2 may be disposed in another first scribe lane region SR1. In this case, the first optical module OM1 and the second optical module OM2 may be disposed spaced apart in a direction perpendicular to the illustrated direction of movement. For example, the first optical module OM1 and the second optical module OM2 may be disposed side by side. In some implementations, the long-wavelength laser beam may be provided to the first optical module OM1 and the second optical module OM2. Since the long-wavelength laser beam is provided to the first optical module OM1 and the second optical module OM2, the first additional laser beam LA1 and the second additional laser beam LA2 may be emitted onto the backside WFb of the wafer WF. In some implementations, since the focuses of the first additional laser beam LA1 and the second additional laser beam LA2 are set inside the wafer WF, the first additional laser beam LA1 and the second additional laser beam LA2 may not etch a portion of the backside WFb of the wafer WF or the backside layer BL and may etch a portion of the backside layer BL or a very small portion of the backside WFb of the wafer WF. In some implementations, the first optical module OM1 and the second optical module OM2 may have focusing points corresponding to position levels that are equal or similar to each other.

In some implementations, the long-wavelength laser beam may be provided from at least one laser beam source. For example, the long-wavelength laser beam may be provided from one laser beam source and may be provided to the first optical module OM1 and the second optical module OM2. For example, the long-wavelength laser beams may be provided from laser beam sources, respectively, and may be provided to the first optical module OM1 and the second optical module OM2, respectively. In some implementations, the third laser beam L3 may include the first additional laser beam LA1 and the second additional laser beam LA2.

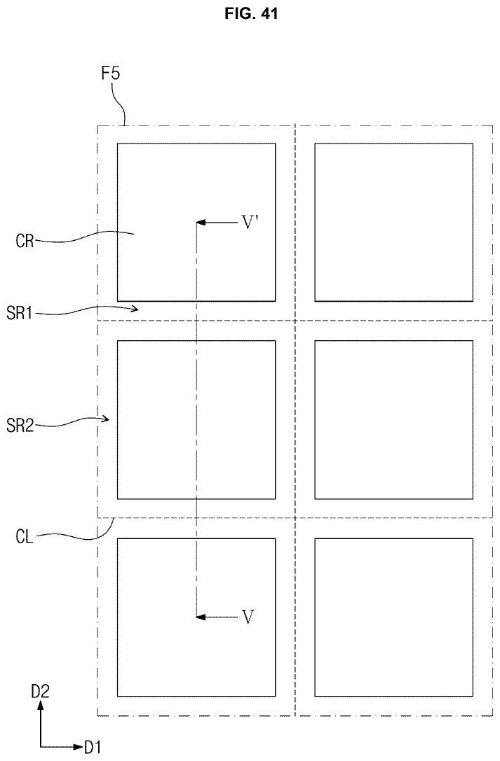

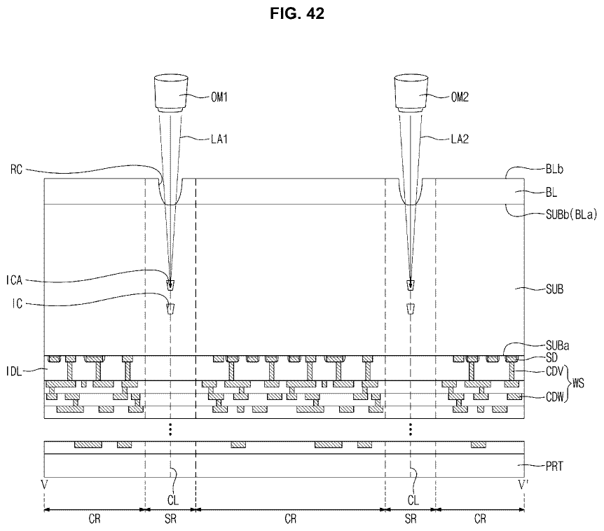

FIG. 41 is a plan view corresponding to ‘F5’ of FIG. 40. FIG. 42 is a sectional view taken along line V-V′ of FIG. 41.

Referring to FIGS. 39 to 42, the first additional laser beam LA1 and the second additional laser beam LA2 may etch a portion inside the wafer WF. In some implementations, the first additional laser beam LA1 and the second additional laser beam LA2 may etch a portion in the base layer SUB. For example, the first additional laser beam LA1 and the second additional laser beam LA2 may form the additional inner cracks ICA in the base layer SUB. In some implementations, the additional inner cracks ICA may be formed in the scribe lane region SR of the wafer WF. For example, the additional inner cracks ICA may vertically overlap the recesses RC. In this case, the additional inner cracks ICA and the recesses RC may be vertically spaced apart from each other. For example, the additional inner cracks ICA may vertically overlap the inner cracks IC. In this case, the additional inner cracks ICA and the inner cracks IC may be vertically spaced apart from each other. In some implementations, the first optical module OM1 and the second optical module OM2 may have focusing points corresponding to position levels that are equal or similar to each other.

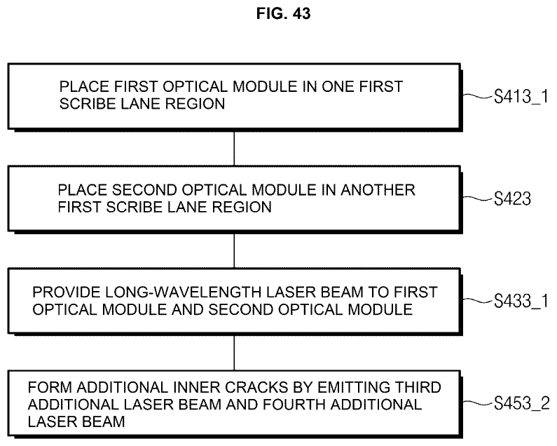

Referring to FIGS. 34 and 43, the emitting of the third laser beam onto the backside layer (S403) in the semiconductor device manufacturing method may include placing the first optical module in one first scribe lane region (S413_1), placing the second optical module in another first scribe lane region (S423), providing a long-wavelength laser beam to the first optical module and the second optical module (S433_1), and forming additional inner cracks by emitting a third additional laser beam and a fourth additional laser beam (S453_2).

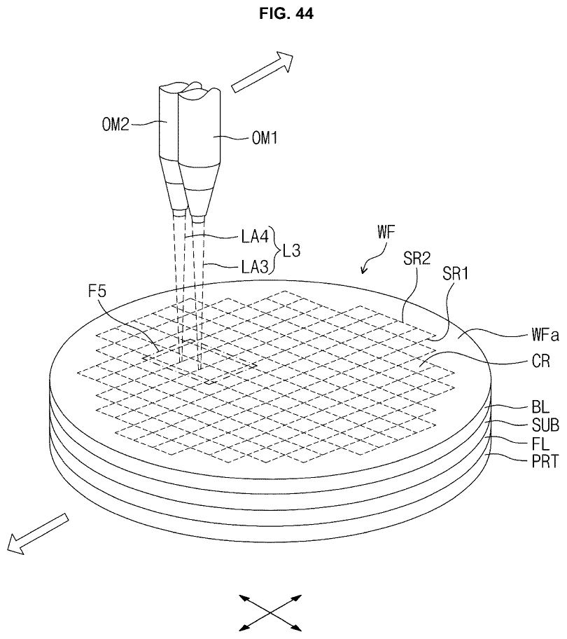

Referring to FIGS. 43 and 44, in some implementations, the long-wavelength laser beam may be provided to the first optical module OM1 and the second optical module OM2. Since the long-wavelength laser beam is provided to the first optical module OM1 and the second optical module OM2, the third additional laser beam LA3 and the fourth additional laser beam LA4 may be emitted onto the backside WFb of the wafer WF. In some implementations, since the focuses of the third additional laser beam LA3 and the fourth additional laser beam LA4 are set inside the wafer WF, the third additional laser beam LA3 and the fourth additional laser beam LA4 may not etch a portion of the backside WFb of the wafer WF or the backside layer BL and may etch a portion of the backside layer BL or a very small portion of the backside WFb of the wafer WF.

In some implementations, the first optical module OM1 and the second optical module OM2 may have focusing points corresponding to position levels that are equal or similar to each other.

In some implementations, the long-wavelength laser beam may be provided from at least one laser beam source. In some implementations, the third laser beam L3 may include the third additional laser beam LA3 and the fourth additional laser beam LA4.

In some implementations, the third laser beam L3 may include the first to fourth additional laser beams LA1, LA2, LA3, and LA4. In this case, the first additional laser beam LA1 and the second additional laser beam LA2 may be focused at points different from the points at which the third additional laser beam LA3 and the fourth additional laser beam LA4 are focused. For example, the first additional laser beam LA1 and the second additional laser beam LA2) may form a first additional inner crack ICA1, and the third additional laser beam LA3 and the fourth additional laser beam LA4 may form a second additional inner crack ICA2.

In addition, the first additional laser beam LA1 and the third additional laser beam LA3 may be laser beams that pass through the first optical module OM1 while forming the additional inner crack ICA, and the second additional laser beam LA2 and the fourth additional laser beam LA4 may be laser beams that pass through the second optical module OM2 while forming the additional inner crack ICA.

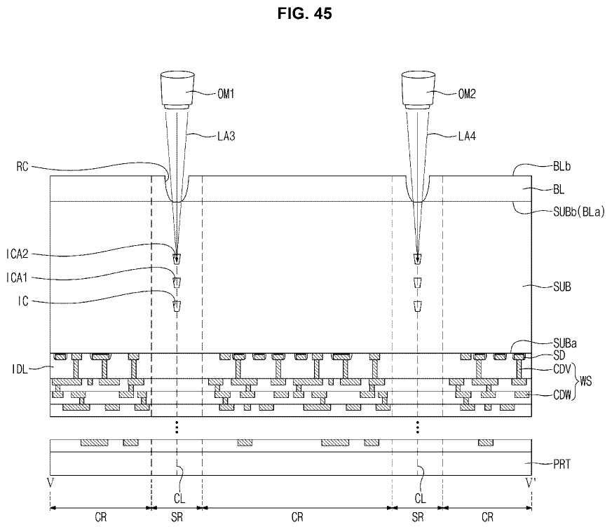

FIG. 45 is a sectional view corresponding to line V-V′ of FIG. 41.

Referring to FIGS. 43 to 45, the third additional laser beam LA3 and the fourth additional laser beam LA4 may etch a portion inside the wafer WF. In some implementations, the third additional laser beam LA3 and the fourth additional laser beam LA4 may etch a portion in the base layer SUB. For example, the third additional laser beam LA3 and the fourth additional laser beam LA4 may form the second additional inner cracks ICA2 in the base layer SUB. The first additional inner cracks ICA1, which are the additional inner cracks ICA formed through the previous process, may be formed by the first additional laser beam LA1 and/or the second additional laser beam LA2. In some implementations, the first additional inner cracks ICA1 and the second additional inner cracks ICA2 may be formed in the scribe lane region SR of the wafer WF. For example, the first additional inner cracks ICA1 may vertically overlap the recesses RC and the inner cracks IC. In this case, the first additional inner cracks ICA1, the recesses RC, and the inner cracks IC may be vertically spaced apart from each other. For example, the second additional inner cracks ICA2 may vertically overlap the recesses RC, the inner cracks IC, and the first additional inner cracks ICA1. In this case, the second additional inner cracks ICA2, the first additional inner cracks ICA1, the recesses RC, and the inner cracks IC may be vertically spaced apart from each other. In some implementations, the first additional inner cracks ICA1 and the second additional inner cracks ICA2 may have different position levels.

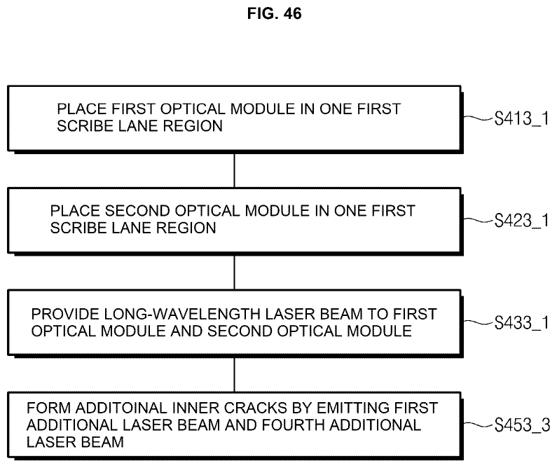

Referring to FIGS. 34 and 46, the emitting of the third laser beam onto the backside layer (S403) in the semiconductor device manufacturing method may include placing the first optical module in one first scribe lane region (S413_1), placing the second optical module in the one first scribe lane region (S423_1), providing a long-wavelength laser beam to the first optical module and the second optical module (S433_1), and forming additional inner cracks by emitting the first additional laser beam and the fourth additional laser beam (S453_3).

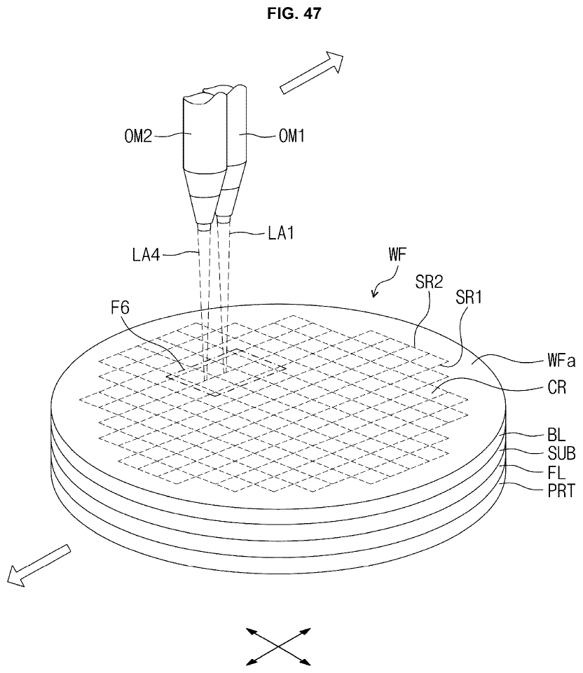

Referring to FIGS. 46 and 47, the first optical module OM1 and the second optical module OM2 may be disposed in the first scribe lane region SR1 of the wafer WF and may be moved along the cut line CL in the first scribe lane region SR1. In some implementations, the first optical module OM1 and the second optical module OM2 may be moved in a horizontal direction such that the laser beams are emitted along the first scribe lane region SR1. For example, the first optical module OM1 and the second optical module OM2 may be moved in directions parallel to the backside WFb of the wafer WF and perpendicular to each other. In some implementations, the stage having the wafer WF mounted thereon may be moved with the first optical module OM1 and the second optical module OM2 fixed, such that the third laser beam L3 is emitted to the first scribe lane region SR1. In some implementations, the stage having the wafer WF mounted thereon, the second optical module OM1, and the second optical module OM2 may be simultaneously moved such that the third laser beam L3 is emitted to the first scribe lane region SR1. In some implementations, the focusing point of the second optical module OM2 may be different from the focusing point of the first optical module OM1.

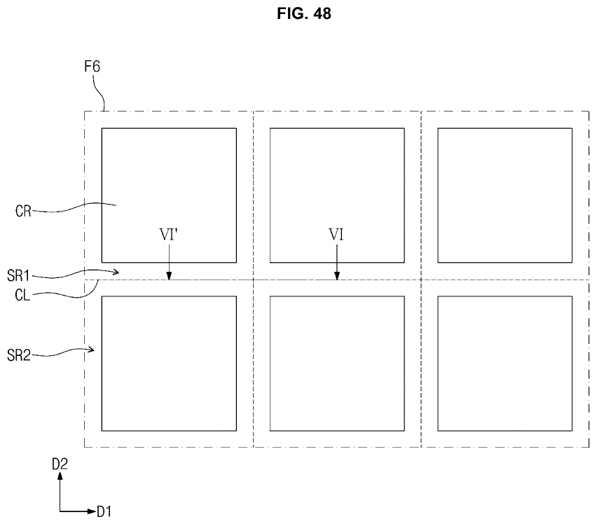

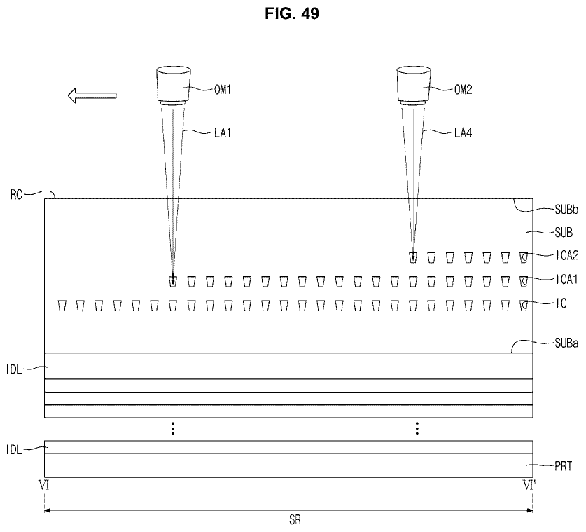

FIG. 48 is a plan view corresponding to ‘F6’ of FIG. 47. FIG. 49 is a sectional view taken along line VI-VI′ of FIG. 48.

Referring to FIGS. 46 to 49, the third laser beam L3 may include long-wavelength laser beams passing through the first optical module OM1 and/or the second optical module OM2. For example, the third laser beam L3 may include the first additional laser beam LA1 passing through the first optical module OM1 and the fourth additional laser beam LA4 passing through the second optical module OM2. In some implementations, the first additional inner crack ICA1 and the second additional inner crack ICA2 may be formed by the first additional laser beam LA1 and the fourth additional laser beam LA4 emitted onto the wafer WF.

Referring to FIGS. 1, 2, 19, 34, 46, 47, and 49, the forming of the first additional inner crack by emitting the first additional laser beam and the forming of the second additional inner crack by emitting the fourth additional laser beam (S453_3) may be simultaneously performed. In this case, the first optical module OM1 may have a focusing point different from the focusing point of the second optical module OM2, and the second optical module OM2 may be spaced apart from the first optical module OM1 and may continuously follow the movement path of the first optical module OM1. Accordingly, the first additional laser beam LA1 and the fourth additional laser beam LA4 may be simultaneously emitted in terms of time and may be emitted to different points in terms of space. In some implementations, the first additional laser beam LA1 may be emitted to form the first additional inner crack ICA1 in the base layer SUB, and the fourth additional laser beam LA4 may be emitted to form the second additional inner crack ICA2 in the base layer SUB. In this case, the first additional inner crack ICA1 and the second additional inner crack ICA2 may vertically overlap each other.

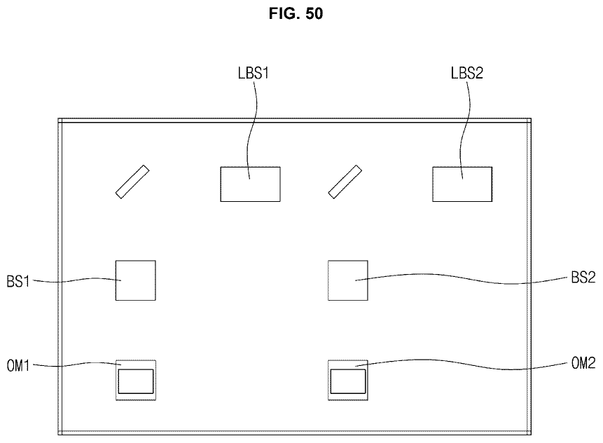

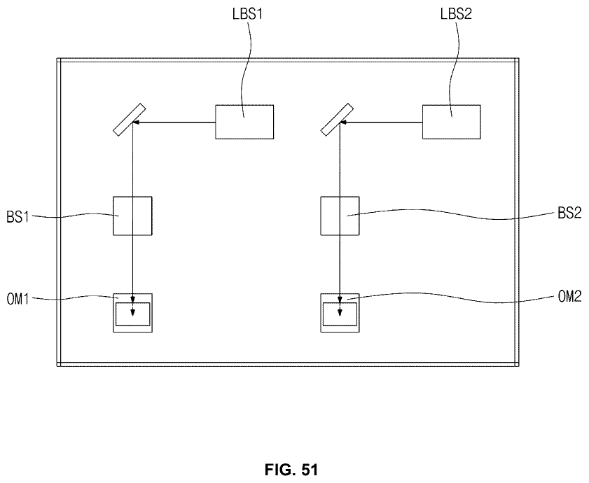

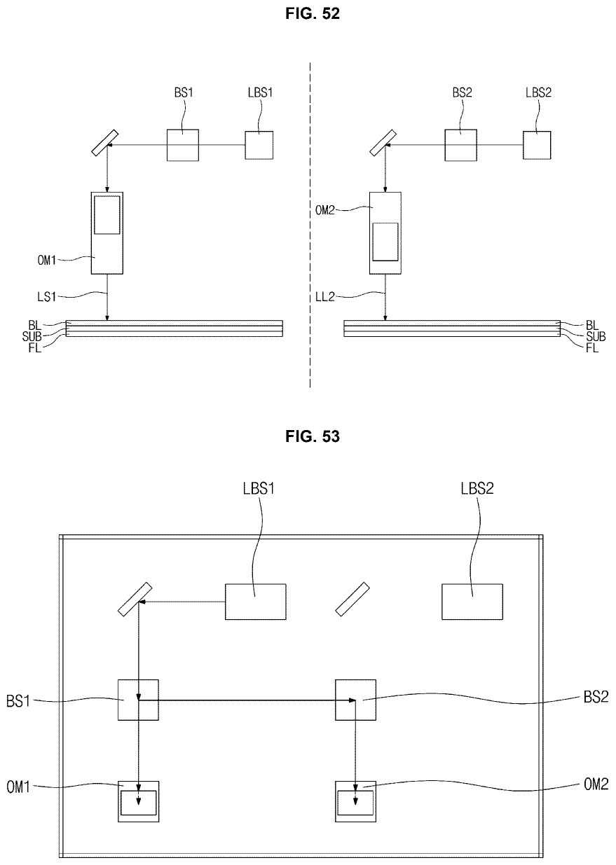

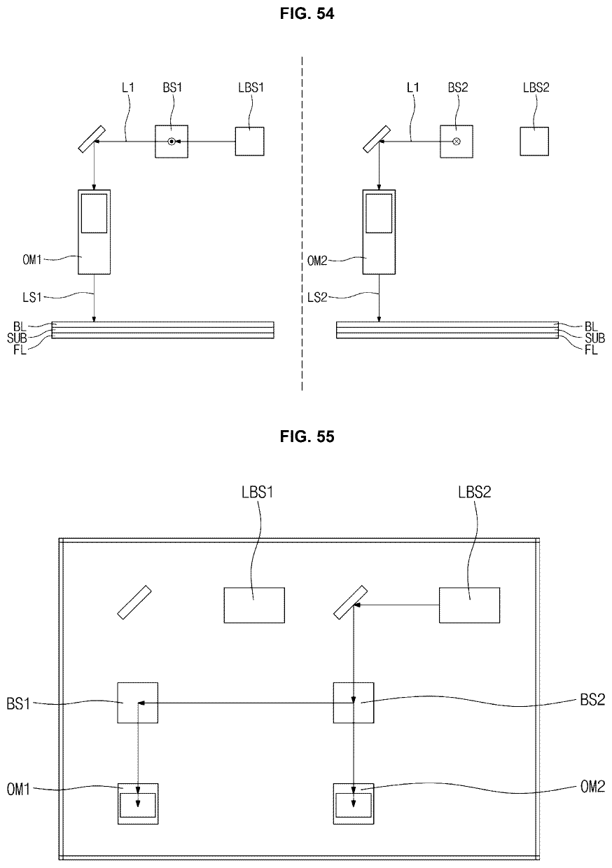

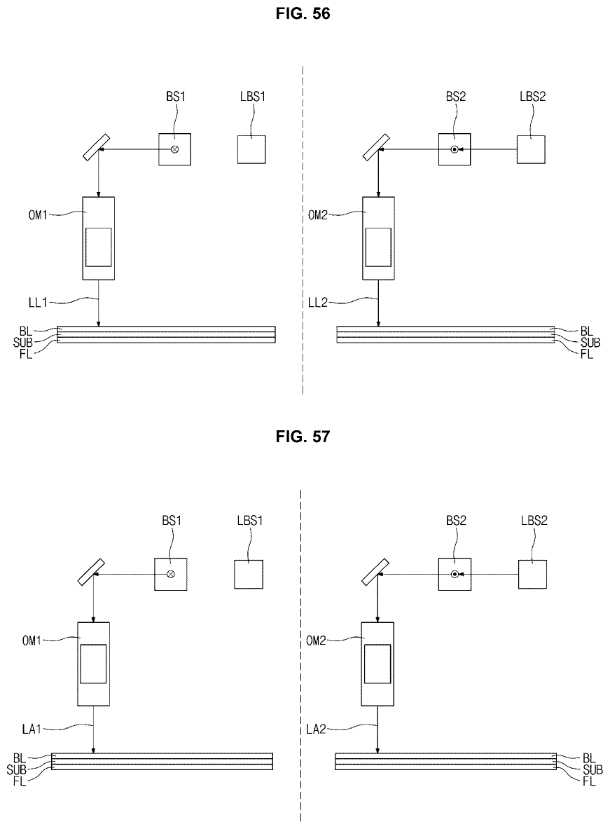

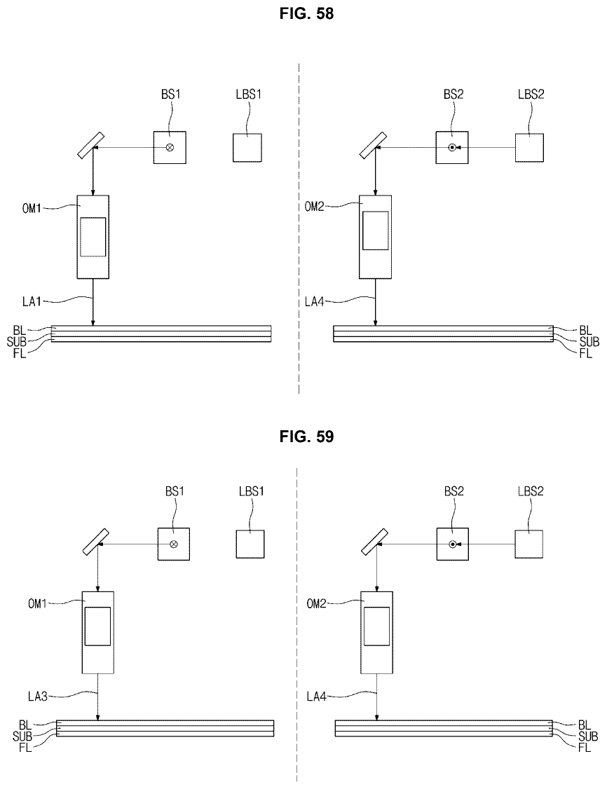

FIGS. 50, 51, 53, and 55 are block diagrams illustrating an example of the laser cutting apparatus. FIGS. 52, 54, and 56 to 59 are block diagrams illustrating a side view of the laser cutting apparatus. FIG. 52 corresponds to the configuration of FIG. 51. FIG. 54 corresponds to the configuration of FIG. 53. FIGS. 56 to 59 correspond to the configuration of FIG. 55.

Referring to FIG. 50, the laser cutting apparatus LCA may be an apparatus that cuts an object being processed, for example the wafer WF, using a laser beam. The wafer WF, which includes the base layer SUB, the frontside layer FL, and the backside layer BL, may be cut to form at least one semiconductor chip. For example, semiconductor chips may be manufactured by cutting the wafer WF.

The laser cutting apparatus LCA may include a first laser beam source LBS1, a second laser beam source LBS2, a first beam splitter BS1, a second beam splitter BS2, the first optical module OM1, and the second optical module OM2. The laser cutting apparatus LCA may include one or more mirrors, illustrated as narrow, reflective rectangles.

A laser beam source, which is a laser oscillator, may continuously or discontinuously generate a laser beam. In some implementations, the laser beam source may generate a femtosecond pulse laser beam. The laser beam may be a laser having a short pulse width of about 10⁻¹⁵ seconds. However, the type of the laser beam is not limited thereto, and the laser beam source may generate a picosecond pulse laser beam.

The laser beam source may include a laser gain medium for oscillating the laser beam and a nonlinear crystal medium for modulating the wavelength of the laser beam. The laser gain medium may include a solid medium or a non-solid medium. The properties of the laser beam may vary depending on the laser gain medium. For example, the laser gain medium may include a neodymium yttrium aluminum garnet compound (Nd:yAG), a neodymium yttrium orthovanadate compound (Nd:yVO4), an aluminum gallium arsenide compound (AlGaAS), an aluminum gallium indium compound (AlGaInP), a gallium nitride compound (GaN), a neodymium optical fiber (Nd-Fiber), or sapphire. In some implementations, the nonlinear crystal medium may include a KTiOPO4 (KTP) crystal.

In some implementations, the laser beam source may include the first laser beam source LBS1 and the second laser beam source LBS2. A laser beam generated from the first laser beam source LBS1 may have a shorter wavelength than a laser beam generated from the second laser beam source LBS2. For example, the first laser beam source LBS1 may generate a short-wavelength laser beam, and the second laser beam source LBS2 may generate a long-wavelength laser beam.

A beam splitter may be a splitting optical system that splits the laser beam output from the laser beam source into a plurality of beams. For example, the beam splitter may transmit a portion of the laser beam and reflect the remaining portion of the laser beam by adjusting the transmittance. In this case, the portion of the laser beam may be provided to one optical module, and the remaining portion of the laser beam may be provided to another optical module. The beam splitter may include the first beam splitter BS1 and the second beam splitter BS2.

In some implementations, the first beam splitter BS1 may provide the laser beam generated from the first laser beam source LBS1 to the first optical module OM1 and/or the second beam splitter BS2. For example, the first beam splitter BS1 may set the transmittance to 100% to provide the laser beam of the first laser beam source LBS1 to the first optical module OM1. For example, the first beam splitter BS1 may set the transmittance to be greater than 0% and less than 100% to provide the laser beam of the first laser beam source LBS1 to the first optical module OM1 and the second beam splitter BS2, as shown in FIG. 53. For example, the first beam splitter BS1 may set the transmittance to 0% to provide the laser beam of the first laser beam source LBS1 to the second beam splitter BS2. For example, the first beam splitter BS1 may provide the laser beam provided from the second beam splitter BS2 to the first optical module OM1.

In some implementations, the second beam splitter BS2 may provide the laser beam generated from the second laser beam source LBS2 to the second optical module OM2 and/or the first beam splitter BS1. For example, the second beam splitter BS2 may set the transmittance to 100% to provide the laser beam of the second laser beam source LBS2 to the second optical module OM2. For example, the second beam splitter BS2 may set the transmittance to be greater than 0% and less than 100% to provide the laser beam of the second laser beam source LBS2 to the second optical module OM2 and the first beam splitter BS1, as shown in FIG. 55. For example, the second beam splitter BS2 may set the transmittance to 0% to provide the laser beam of the second laser beam source LBS2 to the first beam splitter BS1. In some implementations, the second beam splitter BS2 may provide the laser beam provided from the first beam splitter BS1 to the second optical module OM2.

The optical module may include at least one lens and may focus a provided laser beam through the lens. The laser beam may be focused through the optical module and may be applied to the wafer WF that is an object being processed. In some implementations, the optical module may adjust the position of the at least one lens to control the point where the laser beam is focused. In some implementations, the optical module may include the first optical module OM1 and the second optical module OM2. The first optical module OM1 may focus the laser beam onto the first focusing point. The second optical module OM2 may focus the laser beam onto the second focusing point.

In accordance with the semiconductor device manufacturing methods described above, the recess RC may be formed by selectively removing the backside layer BL of the wafer WF by emitting the first laser beam L1, and the inner crack IC overlapping the recess RC may be formed inside the wafer WF by emitting the second laser beam L2 along the formed recess RC. Accordingly, a separate process of removing the backside layer BL on the backside WFb of the wafer WF may be omitted, and thus a process step may be reduced. In addition, the stability of a subsequent process may be improved by removing the backside layer BL or flattening the backside layer BL. For example, the stability of the subsequent process of forming the inner crack may be improved. Thus, the productivity of semiconductor chips by the wafer cutting method may be improved, and as the productivity is improved, the process cost required to manufacture semiconductors may be reduced. In addition, transit time between processes may be reduced, and product quality may be improved by minimizing contamination between the processes.

Some implementations of the semiconductor device manufacturing methods described above may etch at least a portion of the backside layer using the laser beam.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples, it will be apparent to those of ordinary skill in the art that various changes and modifications may be made thereto without departing from the spirit and scope of the present disclosure as set forth in the following claims.

What is claimed is:

1. A wafer cutting method comprising:
forming a backside layer on a backside of a wafer, wherein the wafer comprises chip regions and a scribe lane region spacing the chip regions apart from one another;
forming a recess in the backside layer by emitting a first laser beam onto the backside layer;
forming an inner crack inside the wafer by emitting a second laser beam into the wafer through the backside, wherein the inner crack vertically overlaps the recess, wherein the second laser beam has a wavelength longer than a wavelength of the first laser beam; and
separating the chip regions from each other using the inner crack.

2. The wafer cutting method of claim 1, wherein the backside layer has a first side adjacent to the backside of the wafer and a second side opposite the first side, and
wherein the emitting of the first laser beam onto the backside layer includes emitting the first laser beam onto the second side of the backside layer, such that the recess is recessed from the second side toward the first side.

3. The wafer cutting method of claim 1, wherein the emitting of the first laser beam and the emitting of the second laser beam are performed simultaneously.

4. The wafer cutting method of claim 1, further comprising:
forming, inside the wafer, an additional inner crack that vertically overlaps, and is spaced apart from, the inner crack by emitting a third laser beam into the wafer through the backside, before separating the chip regions from each other.

5. The wafer cutting method of claim 1, wherein the scribe lane region includes:
first scribe lane regions extending parallel to each other in a first direction and spaced apart from each other; and
second scribe lane regions extending parallel to each other in a second direction crossing the first direction and spaced apart from each other.

6. The wafer cutting method of claim 5, wherein the emitting of the first laser beam and the emitting of the second laser beam are performed by a laser cutting apparatus,
wherein the laser cutting apparatus includes:
a first laser beam source configured to generate a short-wavelength laser beam having a first wavelength;
a second laser beam source configured to generate a long-wavelength laser beam having a second wavelength that is longer than the first wavelength;
a first optical module configured to set a first focusing point; and
a second optical module configured to set a second focusing point different from the first focusing point,
wherein the emitting of the first laser beam comprises emitting a first short-wavelength laser beam generated by focusing the short-wavelength laser beam through the first optical module and a second short-wavelength laser beam generated by focusing the short-wavelength laser beam through the second optical module, and
wherein the emitting of the second laser beam comprises emitting a first long-wavelength laser beam generated by focusing the long-wavelength laser beam through the first optical module and a second long-wavelength laser beam generated by focusing the long-wavelength laser beam through the second optical module.

7. The wafer cutting method of claim 6, wherein the emitting of the first laser beam includes:
generating, by the first laser beam source, the short-wavelength laser beam;
generating the first short-wavelength laser beam by focusing a portion of the short-wavelength laser beam through the first optical module;
generating the second short-wavelength laser beam by focusing a remaining portion of the short-wavelength laser beam through the second optical module; and
emitting the first short-wavelength laser beam and the second short-wavelength laser beam to two first scribe lane regions among the first scribe lane regions, respectively, to form, in the backside layer, two recesses in the two first scribe lane regions, respectively.

8. The wafer cutting method of claim 7, wherein the emitting of the second laser beam includes:
generating, by the second laser beam source, the long-wavelength laser beam;
generating the first long-wavelength laser beam by focusing a portion of the long-wavelength laser beam through the first optical module;
generating the second long-wavelength laser beam by focusing a remaining portion of the long-wavelength laser beam through the second optical module; and
emitting the first long-wavelength laser beam and the second long-wavelength laser beam into the wafer through the backside at positions vertically overlapping the two recesses, to form two inner cracks inside the wafer and vertically overlapping the two recesses, respectively.

9. The wafer cutting method of claim 7, comprising:
forming, inside the wafer, an additional inner crack that vertically overlaps the inner crack by emitting a third laser beam into the wafer through the backside at a position vertically overlapping the recess, before the separating of the chip regions.

10. The wafer cutting method of claim 9, wherein the emitting of the third laser beam includes:
generating, by the second laser beam source, the long-wavelength laser beam;
generating a first additional laser beam by focusing a portion of the long-wavelength laser beam through the first optical module;
generating a second additional laser beam by focusing a remaining portion of the long-wavelength laser beam through the second optical module; and
emitting the first additional laser beam and the second additional laser beam into the wafer through the backside at positions vertically overlapping the two recesses, respectively, to form two additional inner cracks inside the wafer and vertically overlapping the two recesses, respectively.

11. The wafer cutting method of claim 7, comprising:
forming a first additional inner crack and a second additional inner crack inside the wafer by emitting a third laser beam into the wafer through the backside configured to overlap the recess, before the separating of the chip regions,
wherein the third laser beam includes a first additional laser beam generated by focusing the long-wavelength laser beam through the first optical module and a fourth additional laser beam generated by focusing the long-wavelength laser beam through the second optical module,
wherein the first additional laser beam forms the first additional inner crack, wherein the first additional inner crack vertically overlaps the recess, and
wherein the fourth additional laser beam forms the second additional inner crack, wherein the second additional inner crack vertically overlaps the first additional inner crack.

12. The wafer cutting method of claim 11, wherein the emitting of the third laser beam includes:
generating, by the second laser beam source, the long-wavelength laser beam;
generating the first additional laser beam by focusing a portion of the long-wavelength laser beam through the first optical module;
generating the fourth additional laser beam by focusing a remaining portion of the long-wavelength laser beam through the second optical module;
emitting the first additional laser beam into the wafer through the backside at positions vertically overlapping the two recesses, respectively, to form two first additional inner cracks inside the wafer and vertically overlapping the two recesses, respectively; and
emitting the fourth additional laser beam into the wafer through the backside at positions vertically overlapping the two recesses, respectively, to form two second additional inner cracks inside the wafer and vertically overlapping the two recesses, respectively.

13. The wafer cutting method of claim 1, comprising:
laminating a protective sheet on a frontside of the wafer, before the emitting of the first laser beam onto the backside layer.

14. The wafer cutting method of claim 1, comprising:
grinding the backside of the wafer, before the separating of the chip regions from each other.

15. A wafer cutting method comprising:
forming a backside layer on a backside of a wafer, wherein the wafer comprises chip regions and a scribe lane region spacing the chip regions apart from one another;
forming a recess in the backside layer by emitting a first laser beam onto the backside layer;
and forming an inner crack inside the wafer by emitting a second laser beam into the wafer through the backside, wherein the inner crack vertically overlaps the recess,
wherein the emitting of the first laser beam and the emitting of the second laser beam are performed in a same scan of an optical module with respect to the wafer or the wafer with respect to the optical module, wherein the optical module emits the first laser beam and the second laser beam.

16. The wafer cutting method of claim 15, wherein the first laser beam has a shorter wavelength than the second laser beam.

17. The wafer cutting method of claim 15, wherein the emitting of the first laser beam and the emitting of the second laser beam include:
focusing the first laser beam at a first vertical level, and
focusing the second laser beam at a second vertical level different from the first vertical level.

18. The wafer cutting method of claim 15, further comprising:
forming, inside the wafer, an additional inner crack that vertically overlaps the inner crack, by emitting a third laser beam into the wafer through the backside at a position vertically overlapping the recess, after the emitting of the second laser beam.

19. The wafer cutting method of claim 18, wherein the emitting of the third laser beam includes:
generating a long-wavelength laser beam;
generating a first additional laser beam by focusing a portion of the long-wavelength laser beam;
generating a fourth additional laser beam by focusing a remaining portion of the long-wavelength laser beam;
emitting the first additional laser beam into the wafer through the backside at a position vertically overlapping the recess, such that a first additional inner crack is formed inside the wafer; and
emitting the fourth additional laser beam into the wafer through the backside at a position vertically overlapping the recess, such that a second additional inner crack is formed inside the wafer, and
wherein the emitting of the first additional laser beam and the emitting of the fourth additional laser beam are performed in a same second scan of the optical module with respect to the wafer or the wafer with respect to the optical module, wherein the optical module emits the first additional laser beam and the fourth additional laser beam.

20. A wafer cutting method comprising:
forming a backside layer on a backside of a wafer, wherein the wafer comprises chip regions and a scribe lane region spacing the chip regions apart from one another;
forming a recess in the backside layer by emitting a first laser beam onto the backside layer;
forming an inner crack inside the wafer by emitting a second laser beam into the wafer through the backside, wherein the inner crack vertically overlaps the recess; and
forming an additional inner crack inside the wafer by emitting a third laser beam into the wafer through the backside, wherein the additional inner crack vertically overlaps the recess,
wherein the emitting of the second laser beam and the emitting of the third laser beam are performed in a same scan of an optical module with respect to the wafer or the wafer with respect to the optical module, wherein the optical module emits the first laser beam, the second laser beam, and the third laser beam.
